(19) United States
(12) Patent Application Publication
(10) Pub. No.: US 2026/0020418 A1
(43) Pub. Date: Jan. 15, 2026

(54) INORGANIC LIGHT-EMITTING DIODE, LIGHT-EMITTING PANEL AND BACKLIGHT MODULE

(71) Applicants: BOE MLED Technology Co., Ltd., Beijing (CN); BOE TECHNOLOGY GROUP CO., LTD., Beijing (CN)

(72) Inventors: Bao FU, Beijing (CN); Qibing GU, Beijing (CN); Lili JIA, Beijing (CN); Lingyun SHI, Beijing (CN); Changhao WANG, Beijing (CN); Xiuling LI, Beijing (CN); Ming CHEN, Beijing (CN); Xue DONG, Beijing (CN); Peng LIU, Beijing (CN); Hao ZHOU, Beijing (CN)

(21) Appl. No.: 18/992,590

(22) PCT Filed: Jul. 22, 2022
(86) PCT No.: PCT/CN2022/107492

§ 371 Date: Jan. 9, 2025

(51) Int. Cl. H10H 29/85; H10H 29/24

(52) U.S. Cl. CPC H10H 29/857; H10H 29/24

(57) ABSTRACT

A light-emitting panel includes at least one light-emitting control region. In any one of the at least one light-emitting control region, the light-emitting panel includes inorganic light-emitting diodes distributed in an array and includes at least one first line extending along a first direction and at least one second line extending along a second direction. One of the inorganic light-emitting diodes has a plurality of first pins and a second pin. A first pin of one of two inorganic light-emitting diodes adjacent along the first direction is electrically connected to an adjacent first pin of the other one of the two inorganic light-emitting diodes through a corresponding first line, the second pin of one of the inorganic light-emitting diodes is electrically connected to a corresponding second line.

### TECHNICAL FIELD

The present disclosure relates to the field of display technologies, and specifically to an inorganic light-emitting diode, a light-emitting panel and a backlight module.

### BACKGROUND

Light-emitting diode (LED) light boards used as light sources of direct backlight modules are increasingly applied in liquid crystal display devices. A driving substrate of a LED light board needs to be provided with multiple metal layers, or a large number of jumper resistors need to be provided on the LED light board to electrically interconnect LED beads arranged in an array. These structures have hindered the cost reduction of LED light boards.

It should be noted that the information disclosed in the above background section is only used to enhance understanding of the background of the present disclosure, and therefore may include information that does not constitute prior art known to those of ordinary skill in the art.

### SUMMARY

The purpose of the present disclosure is to provide an inorganic light-emitting diode, a light-emitting panel and a backlight module which can reduce the cost of the light-emitting panel so as to overcome the shortcomings of related art.

According to an aspect of the present disclosure, there is provided a light-emitting panel, including at least one light-emitting control region, wherein in any one of the at least one light-emitting control region, the light-emitting panel includes inorganic light-emitting diodes distributed in an array and includes a first line extending along a first direction and a second line extending along a second direction;
wherein the inorganic light-emitting diode has a plurality of first pins and a second pin, and the plurality of first pins are electrically connected inside the inorganic light-emitting diode;
wherein two adjacent first pins of two inorganic light-emitting diodes adjacent along the first direction are electrically connected through the first line, the second pin of each of the inorganic light-emitting diodes is electrically connected to the second line, and the second line passes through a region where an inorganic light-emitting diode is located by passing between two first pins of the inorganic light-emitting diode.

According to an implementation of the present disclosure, the number of the plurality of first pins of the inorganic light-emitting diode is two, and the two first pins are arranged along the first direction.

According to an implementation of the present disclosure, the light-emitting panel includes a base substrate, a metal wiring layer, an insulating layer and an electronic element layer that are stacked in sequence. The metal wiring layer is provided with the first line and the second line. The insulating layer covers the metal wiring layer and has openings that expose a local region of the first line and a local region of the second line;
the electronic element layer includes the inorganic light-emitting diodes, the first pins of the inorganic light-emitting diode are electrically connected to the first line through the openings, and the second pin of the inorganic light-emitting diode is electrically connected to the second line through the opening.

According to an implementation of the present disclosure, in the light-emitting control region, the inorganic light-emitting diodes are arranged as a plurality of pixel rows and a plurality of pixel columns, the pixel row includes a plurality of the inorganic light-emitting diodes arranged sequentially along the first direction, and the pixel column includes a plurality of the inorganic light-emitting diodes arranged sequentially along the second direction;
wherein the light-emitting control region has a plurality of signal channels, each of the signal channels includes one pixel row or a plurality of adjacent pixel rows, and the first pins of each of the inorganic light-emitting diodes in the signal channels are electrically connected;
wherein second pins of inorganic light-emitting diodes in the pixel column are connected to one or more second lines, and if there are a plurality of inorganic light-emitting diodes located in a same pixel column and in a same signal channel, the second pins of the plurality of inorganic light-emitting diodes are connected to different second lines, respectively.

According to an implementation of the present disclosure, the signal channel includes one pixel row, and the second pins of each of the inorganic light-emitting diodes in the pixel column are connected to a same second line.

According to an implementation of the present disclosure, the signal channel includes two adjacent pixel rows, the second pins of the inorganic light-emitting diodes in the pixel column are connected to two second lines, respectively, and the two second lines pass through a region where an inorganic light-emitting diode is located by passing between two first pins of the inorganic light-emitting diode.

According to an implementation of the present disclosure, the signal channel includes three adjacent pixel rows, the second pins of the inorganic light-emitting diodes in the pixel columns are connected to three second lines, respectively, and the three second lines pass through a region where an inorganic light-emitting diode is located by passing between two first pins of the inorganic light-emitting diode.

According to an implementation of the present disclosure, the light-emitting panel further includes: first pads and first interconnect lines which are in a one-to-one correspondence with the signal channels, and second pads and second interconnect lines which are in a one-to-one correspondence with second lines;
wherein at least one first line in the signal channel and a corresponding first pad are electrically connected through a corresponding first interconnect line;
wherein the second line and a corresponding second pad are electrically connected through a corresponding second interconnect line.

According to an implementation of the present disclosure, at least one second interconnect line or at least one first interconnect line includes a plurality of sections of interconnect sub-lines which are arranged in a same layer as the first line, and two adjacent interconnect sub-lines are electrically connected through a jumper resistor arranged in a same layer as the inorganic light-emitting diode.

According to an implementation of the present disclosure, the light-emitting panel further includes: a plurality of second control chips arranged along the first direction, and a plurality of first control chips arranged along the second direction;
wherein the first control chip has one or more first output pins, and the one or more first output pins are used to apply a first voltage to a first line of a corresponding signal channel under control of the first control chip;
wherein the second control chip has one or more second output pins, and the one or more second output pins are used to apply a second voltage to a corresponding second line under control of the second control chip;
wherein the inorganic light-emitting diode emits light under control of the first voltage and the second voltage.

According to an implementation of the present disclosure, the first control chip includes a data input pin and a data output pin, and in two adjacent first control chips, a data output pin of one of the two first control chips is electrically connected to a data input pin of the other one of the two first control chips through a first data line which is arranged in a same layer as the first line;
wherein the light-emitting panel further includes a plurality of first power supply lines which are arranged in a same layer as the first line and extend along the second direction, and the first power supply lines are used to provide a required voltage to the first control chips.

According to an implementation of the present disclosure, in a plurality of adjacent first control chips, a same first power supply line is electrically connected to each of the plurality of first control chips.

According to an implementation of the present disclosure, the first control chip includes multiple types of power pins, the number of each type of power pins is two and each type of power pins are arranged oppositely along the second direction, and two power pins of a same type are electrically connected inside the first control chip;
wherein among a plurality of adjacent first control chips, two adjacent power pins of a same type in two adjacent first control chips are electrically connected through a first power supply line.

According to an implementation of the present disclosure, the first pins are anode pins;
wherein the first power supply lines includes a first reference voltage line for applying a reference voltage signal to the first control chips, a first chip power supply line for applying a chip power supply voltage to the first control chips, and a driving voltage signal line for applying a driving voltage signal to the first control chips;
wherein when a first output pin outputs the first voltage, the first output pin outputs the driving voltage signal to each connected inorganic light-emitting diode.

According to an implementation of the present disclosure, the second control chip includes a data input pin and a data output pin, and in two adjacent second control chips, a data output pin of one of the two adjacent control chips is electrically connected to a data input pin of the other one of the two adjacent second control chips through a second data line which is arranged in a same layer as the second line;
wherein the light-emitting panel further includes a plurality of second power supply lines which are arranged in a same layer as the second line and extend along the first direction, and the plurality of second power supply lines are used to provide a required voltage to the second control chips.

According to an implementation of the present disclosure, in a plurality of adjacent second control chips, a same second power supply line is electrically connected to each of the plurality of adjacent second control chips.

According to an implementation of the present disclosure, the second control chip includes multiple types of power pins, the number of each type of power pins is two and each type of power pins are arranged oppositely along the first direction, and two power pins of a same type are electrically connected inside the second control chip;
wherein among a plurality of adjacent second control chips, two adjacent power pins of a same type in two adjacent second control chips are electrically connected through a second power supply line.

According to an implementation of the present disclosure, the second pin is a cathode pin;
wherein the second power supply lines includes a second reference voltage line for applying a reference voltage signal to the second control chips and a second chip power supply line for applying a chip power supply voltage to the second control chips, and the second control chips is are to control electrical conduction or cutoff between the second lines and the second reference voltage line.

According to an implementation of the present disclosure, the number of the second pins is two and the second pins are electrically connected within the inorganic light-emitting diode;
wherein at least part of a second line passes through a region where the inorganic light-emitting diode is located by passing between the two second pins.

According to a second aspect of the present disclosure, there is provided a backlight module, including the light-emitting panel described above.

According to a third aspect of the present disclosure, there is provided an inorganic light-emitting diode, wherein the inorganic light-emitting diode has a plurality of first pins and a second pin, and the plurality of first pins are electrically connected inside the inorganic light-emitting diode.

According to an implementation of the present disclosure, the number of the plurality of first pins in the inorganic light-emitting diode is two, and there is a wiring region between the two first pins, and the wiring region is used for laying out at least one line.

According to an implementation of the present disclosure, a width of the wiring region is in a range of 100 to 450 microns.

According to an implementation of the present disclosure, the number of the second pins is two, and the two second pins are electrically connected inside the inorganic light-emitting diode.

It should be understood that the foregoing general description and the following detailed description are exemplary and explanatory only, and do not limit the present disclosure.

### BRIEF DESCRIPTION OF THE DRAWINGS

The accompanying drawings, which are incorporated in and constitute a part of the specification, illustrate embodiments consistent with the present disclosure and together with the specification serve to explain the principles of the present disclosure. Apparently, the drawings in the following description are only some embodiments of the present disclosure, and those skilled in the art may obtain other drawings according to these drawings without creative efforts.

FIG. 1 is a schematic diagram showing the distribution of light-emitting control region(s) of a light-emitting panel in an implementation of the present disclosure.

FIG. 2 is a schematic diagram showing the distribution of light-emitting control region(s) of a light-emitting panel in an implementation of the present disclosure.

FIG. 3 is a schematic diagram of pins of an inorganic light-emitting diode in an implementation of the present disclosure.

FIG. 4 is a schematic diagram of pins of an inorganic light-emitting diode in an implementation of the present disclosure.

FIG. 5 is a schematic diagram showing the structure of an inorganic light-emitting diode in an implementation of the present disclosure.

FIG. 6 is a schematic diagram showing the structure of an inorganic light-emitting diode in an implementation of the present disclosure.

FIG. 7 is a schematic diagram showing the structure of an inorganic light-emitting diode in an implementation of the present disclosure.

FIG. 8 is a schematic diagram showing electrical interconnections of inorganic light-emitting diodes in a light-emitting control region in an implementation of the present disclosure.

FIG. 9 is a schematic cross-sectional view showing a structure of a light-emitting panel in an implementation of the present disclosure.

FIG. 10 is a schematic diagram showing electrical interconnections of inorganic light-emitting diodes in a light-emitting control region in an implementation of the present disclosure.

FIG. 11 is a schematic cross-sectional view showing a structure of a light-emitting panel in an implementation of the present disclosure.

FIG. 12 is a schematic diagram showing electrical interconnections of inorganic light-emitting diodes in a light-emitting control region in an implementation of the present disclosure.

FIG. 13 is a schematic cross-sectional view showing a structure of a light-emitting panel in an implementation of the present disclosure.

FIG. 14 is a schematic diagram showing electrical interconnections of inorganic light-emitting diodes in a light-emitting control region in an implementation of the present disclosure.

FIG. 15 is a schematic diagram showing a structure in which a first line is electrically connected to a first pad through a first interconnect line and a second line is electrically connected to a second pad through a second interconnect line in an implementation of the present disclosure.

FIG. 16 is a schematic diagram showing a structure in which a first line is electrically connected to a first pad through a first interconnect line and a second line is electrically connected to a second pad through a second interconnect line in an implementation of the present disclosure.

FIG. 17 is a schematic diagram showing a structure in which a first line is electrically connected to a first pad through a first interconnect line and a second line is electrically connected to a second pad through a second interconnect line in an implementation of the present disclosure.

FIG. 18 is a schematic diagram showing a structure in which a first line is electrically connected to a first pad through a first interconnect line and a second line is electrically connected to a second pad through a second interconnect line in an implementation of the present disclosure.

FIG. 19 is a schematic diagram showing a structure in which first control chip(s) and second control chip(s) are provided on a light-emitting panel to drive inorganic light-emitting diodes in an implementation of the present disclosure.

FIG. 20 is a schematic diagram showing a structure in which first control chip(s) and second control chip(s) are provided on a light-emitting panel to drive inorganic light-emitting diodes in an implementation of the present disclosure.

FIG. 21 is a schematic diagram showing a structure in which first control chip(s) and second control chip(s) are provided on a light-emitting panel to drive inorganic light-emitting diodes in an implementation of the present disclosure.

FIG. 22 is a schematic diagram showing a structure of an electrical connection relationship between first control chips in an implementation of the present disclosure.

FIG. 23 is a schematic diagram showing a structure of an electrical connection relationship between first control chips in an implementation of the present disclosure.

FIG. 24 is a schematic diagram showing a structure of an electrical connection relationship between second control chips in an implementation of the present disclosure.

FIG. 25 is a schematic diagram showing a structure of an electrical connection relationship between second control chips in an implementation of the present disclosure.

### DETAILED DESCRIPTION

Example implementations will now be described more fully with reference to the accompanying drawings. Example implementations may, however, be embodied in many forms and should not be construed as being limited to the implementations set forth herein; rather, these implementations are provided so that the present disclosure will be thorough and complete, and will fully convey the concept of example implementations to those skilled in the art. The same reference numerals in the drawings indicate the same or similar structures, and thus their detailed descriptions will be omitted. Furthermore, the drawings are merely schematic illustrations of the present disclosure and are not necessarily drawn to scale.

Although relative terms, such as “upper” and “lower” are used in this specification to describe a relative relationship of one component of shown in a figure with respect to another component, these terms are used in this specification only for convenience, for example, these terms are based on a direction illustrated in the drawings. It will be understood that if a device shown in a figure is turned upside down, a component described as “upper” would become a components described as “lower”. When a structure is “on” another structure, it may mean that the structure is integrally formed on another structure, or that the structure is “directly” provided on another structure, or that the structure is “indirectly” provided on anther structure through other structure(s).

The terms “one”, “a/an”, “the”, “said” and “at least one” are used to indicate the presence of one or more elements/components/etc.; the terms “include/comprise” and “have” are used to indicate open-ended inclusion and mean that there may be additional element(s)/component(s)/etc. in addition to those listed; the terms “first”, “second”, “third” etc. are only used as a marker, and are not intended to be construed as a limit on the number of associated objects.

The expression that a structural layer A is located at a side of a structural layer B away from a base substrate can be understood as: the structural layer A is formed on the side of the structural layer B away from the base substrate. When structural layer B is a patterned structure, a part of the structure of the structural layer A may also be located at the same physical height of the structural layer B or lower than the physical height of the structural layer B, where the base substrate is the height reference.

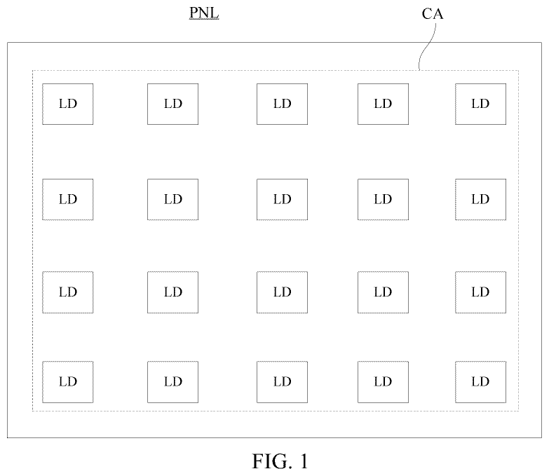

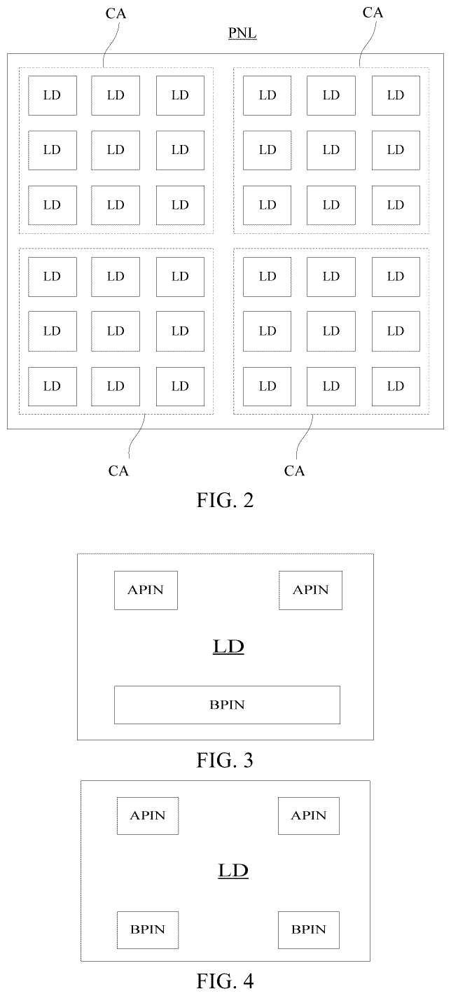

An implementation of the present disclosure provides a light-emitting panel and an inorganic light-emitting diode used in the light-emitting panel. Referring to FIGS. 1 and 2, a light-emitting panel PNL includes at least one light-emitting control region CA. In each light-emitting control region CA, the light-emitting panel PNL includes inorganic light-emitting diodes LD distributed in an array. In this way, the light-emitting panel PNL may be used as a light board of a backlight module, used as a light board of a lighting device, used as a display panel that directly displays a picture, or used in other devices that require a light source.

In related art, an inorganic light-emitting diode has one anode pin and one cathode pin. The anode pin needs to be electrically connected to an anode line for applying a driving voltage signal, and the cathode pin needs to be electrically connected to a cathode line for applying a ground voltage. When there is a voltage difference between voltages applied on the anode line and the cathode line respectively, the inorganic light-emitting diode is in an electrical path and emits light. Generally, in order to facilitate wiring and control, the anode line and the cathode line are arranged to intersect, for example, one of the anode line and the cathode line extends along a row direction and the other one extends along a column direction. In a light-emitting control region, anode line(s) and multiple cathode lines intersect to form a grid shape.

For example, in related art, a first metal layer, an insulating layer and a second metal layer may be disposed in sequence at a side of a base substrate. The first metal layer forms anode lines and the second metal layer forms cathode lines. Alternatively, the first metal layer forms the anode lines and the cathode lines, and the cathode lines are bridged using the second metal layer at intersections with the anode lines. Due to the need to provide two metal layers, light-emitting panel has high cost and poor heat dissipation.

As another example, in related art, only one metal layer may be provided at a side of the base substrate, and the metal layer forms the complete structure of each anode line and a partial structure of each cathode line. The partial structure of a cathode line means that in order to avoid an anode line, the cathode line, which should be a continuous line, is divided into multiple mutually spaced sub-segments, and electrical continuity of the sub-segments is realized through jumper resistors. Thus, multiple jumper resistors need to be set. For example, for inorganic light-emitting diodes of N rows and M columns, N*M jumper resistors need to be set. This not only increases the material cost but also prolong the process cycle time. In some cases, setting the jumper resistors may also adversely affect the uniformity of light output from the light-emitting panel.

In an implementation of the present disclosure, an inorganic light-emitting diode LD may be provided, so that the light-emitting panel PNL can adopt a single layer of metal to lay out anode line(s) and cathode line(s) by using a small number of jumper resistors or without using a jumper resistor.

Referring to FIGS. 3 to 7, an inorganic light-emitting diode LD has first pins APIN and a second pin BPIN. There are multiple first pins APIN and they are electrically connected inside the inorganic light-emitting diode LD. In other words, the inorganic light-emitting diode LD is provided with a plurality of first pins APIN, and the plurality of first pins APIN are electrically connected inside the inorganic light-emitting diode LD. One of the first pins APIN and the second pin BPIN is an anode pin, and the other is a cathode pin. For example, in an example, the first pins APIN are the anode pins and the second pin BPIN is the cathode pin.

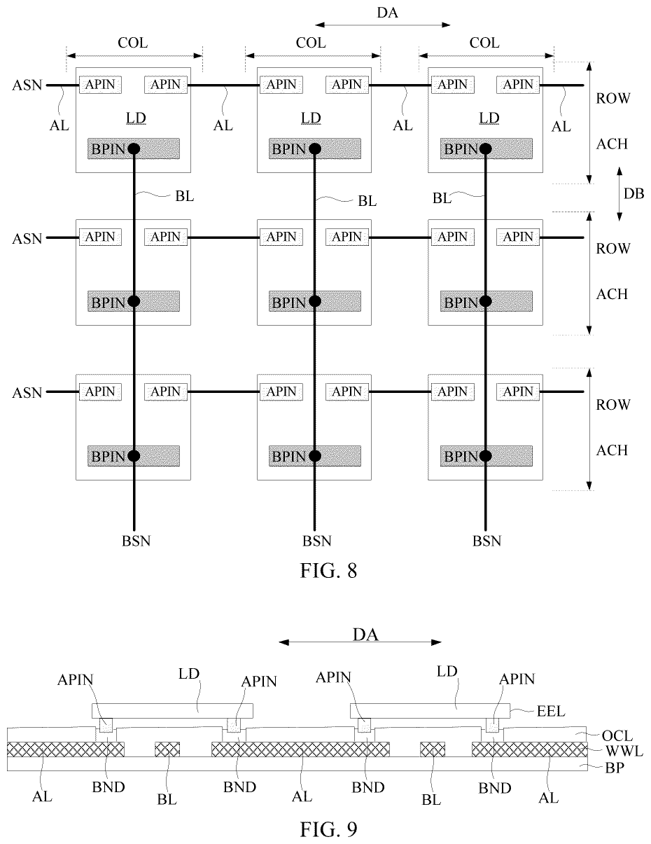

In an example, referring to FIGS. 3 to 7, the number of first pins APIN of the inorganic light-emitting diode LD is two. Referring to FIGS. 8 to 13, the two first pins APIN are arranged along a first direction DA and are spaced apart. In this way, a second line BL may pass between the two first pins APIN. It can be understood that the second line BL is provided on a base substrate, and a region where the inorganic light-emitting diode LD is located refers to an orthographic projection of the inorganic light-emitting diode LD on the base substrate. The second line BL passing through a region where the inorganic light-emitting diode LD is located by passing between the two first pins APIN of the inorganic light-emitting diode LD means that: an orthographic projection of the second line BL on the base substrate overlaps with an orthographic projection of the inorganic light-emitting diode LD on the base substrate, and among the plurality of first pins APIN in one inorganic light-emitting diode LD, there are at least two first pins APIN whose orthographic projections on the base substrate are located at both sides of the second line BL.

Referring to FIGS. 8 to 13, in any one of the light-emitting control regions CA, the light-emitting panel PNL includes first line(s) AL extending along the first direction DA and second line(s) BL extending along a second direction DB. A first line AL is electrically connected to first pins APIN, and a second line BL is electrically connected to second pin(s) BPIN. The functions exerted by the first line(s) AL and the second line BL and the signals needed to be applied are associated with the first pins APIN and the second pins BPIN. When the first pins APIN are the anode pins, the first lines AL are anode lines for applying a driving voltage signal (that is, the anode voltage of the inorganic light-emitting diode LD) to the inorganic light-emitting diode LD; correspondingly, the second pins BPIN are the cathode pins, and the second lines BL are the cathode lines for applying a reference voltage signal to the inorganic light-emitting diode LD. On the contrary, if the second pins BPIN are the anode pins, the second lines BL are the anode lines for applying the driving voltage signal (that is, the anode voltage of the inorganic light-emitting diode LD) to the inorganic light-emitting diode LD; correspondingly, the first pins APIN are the cathode pins, and the first lines AL are the cathode lines for applying the reference voltage signal to the inorganic light-emitting diode LD. The first direction DA and the second direction DB are two directions that intersect with each other, and in particular, the first direction DA and the second direction DB may be two directions that are perpendicular to each other. Further, one of the first direction DA and the second direction DB is a row direction of the light-emitting panel PNL, and the other is a column direction of the light-emitting panel PNL. For example, in an example, the first direction DA is the row direction of the light-emitting panel PNL, and the second direction DB is the column direction of the light-emitting panel PNL. Of course, the first direction DA and the second direction DB may also have an acute angle with the row direction or column direction of the light-emitting panel. It can be understood that in the implementations of the present disclosure, the row direction and the column direction are two relative directions; generally, in two adjacent edges of a rectangular light-emitting panel, the extension direction of one edge is the row direction, and the extension direction of the other edge is the column direction.

Referring to FIGS. 8 to 13, in two adjacent inorganic light-emitting diodes LD along the first direction DA, two adjacent first pins APIN of the two adjacent inorganic light-emitting diodes LD are electrically connected through a first line AL, the second pin BPIN of each of the inorganic light-emitting diodes LD is electrically connected to a second line BL; the second line BL passes through a region where an inorganic light-emitting diode LD is located by passing between two first pins APIN of the inorganic light-emitting diode LD. In this way, two first lines AL adjacent in the first direction can be electrically connected using an inorganic light-emitting diode LD, and any first line AL can be insulated from a second line BL. On the one hand, this solution allows the light-emitting panel PNL to have only one metal layer for wiring, which reduces the preparation cost and facilitates heat dissipation of the light-emitting panel PNL. On the other hand, this solution can also reduce the number of jumper resistors on the light-emitting panel PNL. Thus, the cost of the light-emitting panel PNL is reduced and the uniformity of the light-emitting panel PNL is improved.

The structure, principle and effects of the inorganic light-emitting diode LD and the light-emitting panel PNL in the implementations of the present disclosure will be further introduced and explained below with reference to the accompanying drawings.

Taking FIG. 9 as an example, from the perspective of film layer structure, the light-emitting panel PNL according to an implementation of the present disclosure may include a base substrate BP, a metal wiring layer WWL, an insulating layer OCL and an electronic element layer EEL that are stacked in sequence. The metal wiring layer WWL is provided with the first line(s) AL and the second line(s) BL. The insulating layer OCL covers the metal wiring layer WWL and has openings that expose a local region of the first line(s) AL and a local region of the second line(s) BL. The electronic element layer EEL includes the inorganic light-emitting diodes LD. The first pins APIN of an inorganic light-emitting diode LD are electrically connected to a first line AL through openings. The second pin of the inorganic light-emitting diode LD is electrically connected to a second line BL through an opening.

The metal wiring layer WWL may include a metal material layer, or may include multiple stacked metal material layers. The material of any metal material layer may be a metal element or an alloy. In an example, the thickness of the metal wiring layer WWL is relatively large, for example, the metal wiring layer has a thickness of 500 nanometers to 2 microns, so that the first lines AL and the second lines BL have lower impedance. In an example, the metal wiring layer WWL may have a metal material layer with high conductivity, such as a copper layer or an aluminum layer, to reduce the impedance of the first lines AL and the second lines BL.

The insulating layer OCL may be an inorganic insulating layer or an organic insulating layer, or may be a composite film layer of an inorganic insulating layer and an organic insulating layer. As an example, the insulating layer OCL includes a plurality of stacked inorganic insulating layers (such as a silicon oxide layer, a silicon nitride layer, or a silicon oxynitride layer) and/or an organic resin layer. Referring to FIG. 9, the insulating layer OCL has openings that expose a local region of the first lines AL and a local region of the second lines BL. The exposed regions of the first lines AL and the second lines BL can be used as pads to be connected with the pins of the inorganic light-emitting diodes LD. For example, a pad achieves a solid electrical connection with a pin through a conductive connection structure BND (such as a solder layer). Furthermore, the width of a first line AL or a second line BL may be increased at the opening position, or a side branch structure may be provided to electrically extend to the opening position.

Referring to FIG. 9, the electrical continuity between two adjacent first lines AL is kept through an inorganic light-emitting diode LD, and a second line BL can pass through a gap between two adjacent first lines AL. An orthographic projection of the gap on the electronic element layer EEL is located between two first pins APIN of the inorganic light-emitting diode LD. In this way, there is a wiring region between the two first pins APIN of the inorganic light-emitting diode LD, and the wiring region is used for laying a line (for example, a second line BL in FIG. 9).

In the inorganic light-emitting diode LD, the distance (i.e., the width of the wiring region) between the two first pins APIN may be determined based on the number of expected wirings, the width of the line, and the size of the gap between the lines. Generally, the greater the number of lines that need to be laid and the greater the width of the lines, the greater the distance between the two first pins APIN. In some implementations of the present disclosure, the width of the wiring region is in a range of 100 to 450 microns, which allows one to three lines to be laid in the wiring region.

In an example, as shown in FIG. 9, the width of the wiring region is 120˜180 microns, and a second line BL of 40˜60 microns can pass between the two first pins APIN of the inorganic light-emitting diode LD. For example, the width of the wiring region is 150 microns, and a 50-micron second line BL can be laid between the two first pins APIN of the inorganic light-emitting diode LD.

In another example, as shown in FIG. 11, the width of the wiring region is 200˜300 microns, and two second lines BL of 40˜60 microns can pass between the two first pins APIN of the inorganic light-emitting diode LD. For example, the width of the wiring region is 250 microns, and two 50-micron second lines BL can be laid between the two first pins APIN of the inorganic light-emitting diode LD.

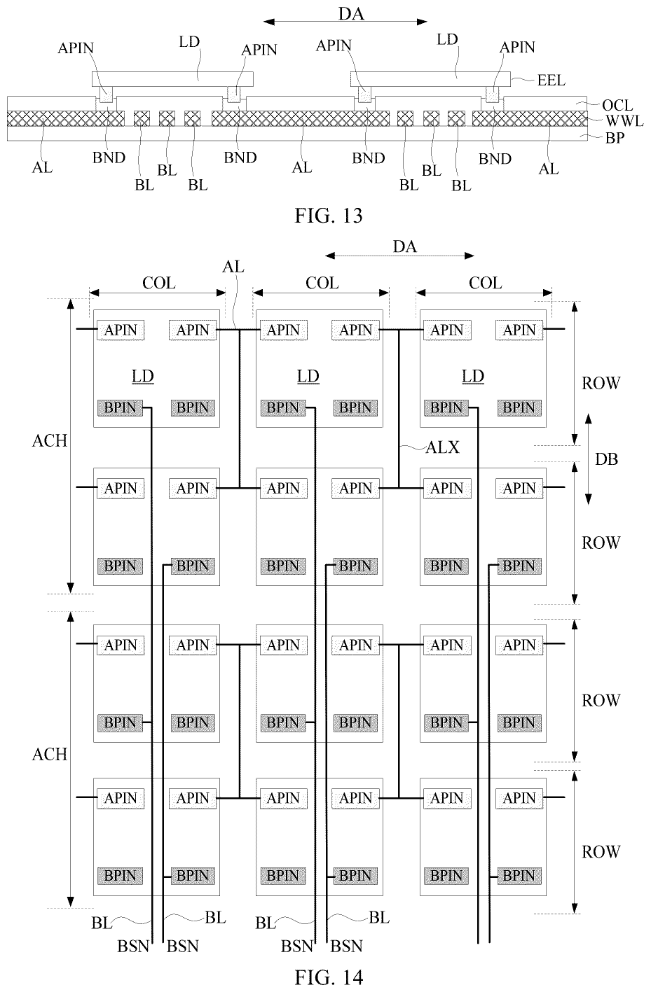

In another example, as shown in FIG. 13, the width of the wiring region is 280˜420 microns, and three second lines BL of 40˜60 microns can pass between the two first pins APIN of the inorganic light-emitting diode LD. For example, the width of the wiring region is 350 microns, and three 50-micron second lines BL can be laid between the two first pins APIN of the inorganic light-emitting diode LD.

In the examples of FIG. 3 and FIG. 4, an inorganic light-emitting diode LD provided by implementations of the present disclosure includes three or four pins, and these pins are divided into two types according to their electrical properties, namely anode pins and cathode pins. Among them, two pins with the same electrical properties, such as two first pins APIN or two second pins BPIN, are electrically connected inside the inorganic light-emitting diode LD. In the example of FIG. 3, the inorganic light-emitting diode LD includes two first pins APIN and one second pin BPIN, and the two first pins APIN are electrically connected inside the inorganic light-emitting diode LD. In the example of FIG. 4, the inorganic light-emitting diode LD includes two first pins APIN and two second pins BPIN. The two first pins APIN are electrically connected inside the inorganic light-emitting diode LD, and the two second pins BPIN are electrically connected inside the inorganic light-emitting diode LD. Referring to FIG. 14, a line can also be laid between the two second pins BPIN. For example, at least part of the second line(s) BL can pass between the second pins BPIN.

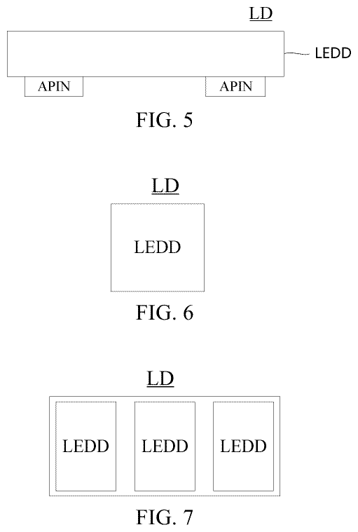

Referring to FIG. 5, the inorganic light-emitting diode LD at least includes a light-emitting structure LEDD and pins. The light-emitting structure LEDD at least includes an N-type semiconductor layer, a multi-quantum well structure layer and a P-type semiconductor layer stacked in sequence. Any first pin of the inorganic light-emitting diode LD is connected to one of the N-type semiconductor layer and the P-type semiconductor layer; any second pin of the inorganic light-emitting diode LD is connected to the other one of the N-type semiconductor layer and the P-type semiconductor layer. In some embodiments, the surfaces of all the first pins and the second pins away from the multi-quantum well structure layer are on the same horizontal plane.

In some embodiments, a ratio between the sum of areas of surfaces of respective first pins APIN in one inorganic light-emitting diode LD away from the multi-quantum well structural layer and the sum of areas of surfaces of respective second pons APIN in the inorganic light-emitting diode LD away from the multi-quantum well structural layer is between 1:3 and 5:9.

In an implementation of the present disclosure, the light-emitting area of the inorganic light-emitting diode LD is greater than 300000 square microns.

In an implementation of the present disclosure, the inorganic light-emitting diode LD may further include one or more of: an encapsulation layer, a color transfer layer (such as a fluorescent layer), or a light modulation layer.

In an implementation of the present disclosure, as shown in FIG. 6, one inorganic light-emitting diode LD may have one light-emitting structure LEDD.

In another implementation of the present disclosure, as shown in FIG. 7, one inorganic light-emitting diode LD may include a plurality of light-emitting structures LEDD. The N-type semiconductor layer of each light-emitting structure LEDD of the plurality of light-emitting structures LEDD is respectively connected to a plurality of first pins of the inorganic light-emitting diode LD, and the P-type semiconductor layer of each light-emitting structure LEDD of the plurality of light-emitting structures LEDD is connected to the same second pin of the inorganic light-emitting diode LD. Alternatively, the P-type semiconductor layer of each light-emitting structure LEDD of the plurality of light-emitting structures LEDD is respectively connected to a plurality of first pins of the inorganic light-emitting diode LD respectively, and the N-type semiconductor layer of each light-emitting structures LEDD of the plurality of light-emitting structures LEDD is connected to the same second pin of inorganic light-emitting diode LD. From the perspective of the arrangement of the inorganic light-emitting diodes LD, see FIGS. 8, 10, 12 and 14, in the light-emitting control region CA, the inorganic light-emitting diodes LD are arranged into multiple pixel rows ROW and multiple pixel columns. COL. A pixel row ROW includes a plurality of inorganic light-emitting diodes LD arranged sequentially along the first direction DA. A pixel column COL includes a plurality of inorganic light-emitting diodes LD arranged sequentially along the second direction DB.

The light-emitting control region CA has a plurality of signal channels ACH. Each of the signal channels ACH includes one pixel row ROW or a plurality of adjacent pixel rows ROW. The first pins APIN of respective inorganic light-emitting diodes LD in a signal channel are electrically connected. In this way, respective inorganic light-emitting diodes LD in the same signal channel ACH can be applied with the same first voltage ASN. When the first pins APIN are anode pins, the first voltage ASN may be a driving voltage signal. When the first pins APIN are cathode pins, the first voltage ASN may be a reference voltage signal. It can be understood that the electrical connection of the first pins APIN of respective inorganic light-emitting diodes LD means that: first pins APIN of each inorganic light-emitting diode LD are electrically interconnected, and two first pins APIN of the inorganic light-emitting diode LD can all be electrically connected to a first line AL, or only one of the first pins APIN can be electrically connected to the first line AL.

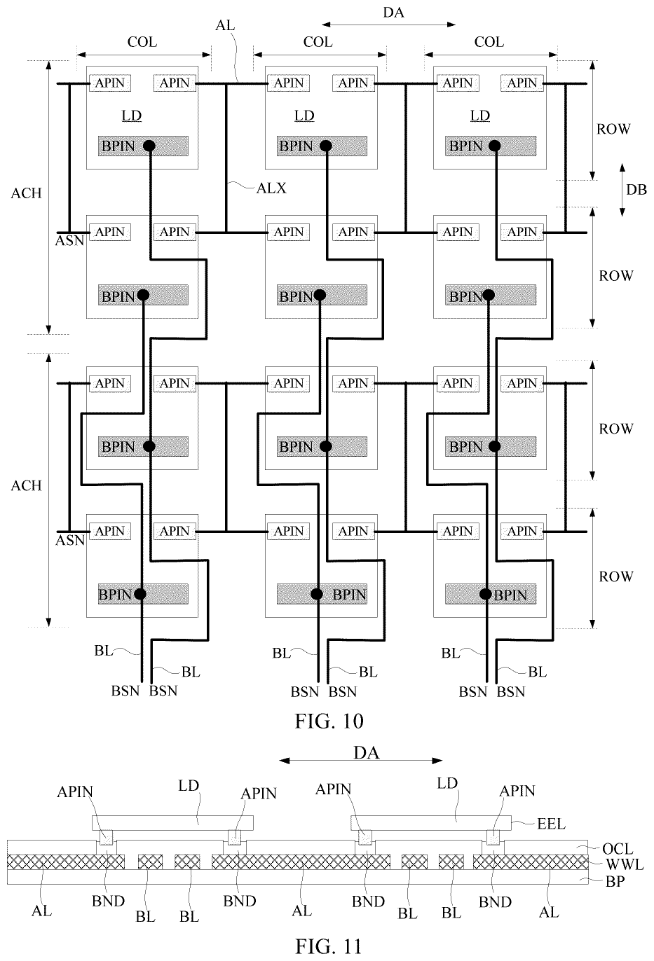

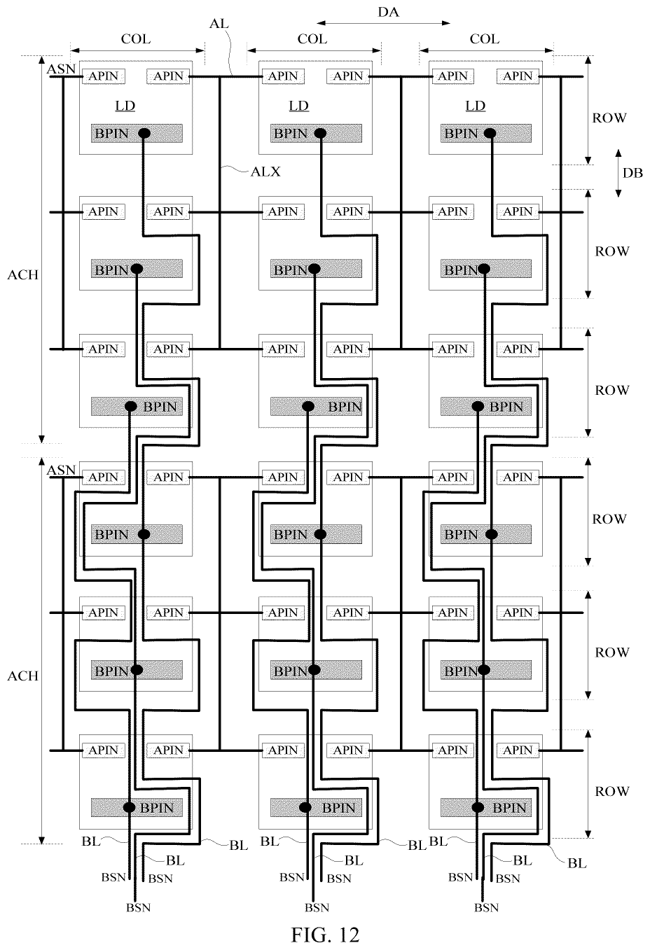

In an example, as shown in FIG. 10, FIG. 12 and FIG. 14, when a signal channel ACH includes a plurality of pixel rows ROW, the light-emitting panel PNL may also be provided with auxiliary line(s) ALX. The inorganic light-emitting diodes LD located in different pixel rows ROW can also be electrically connected through auxiliary line(s) ALX, so that some inorganic diodes LD are connected in parallel to improve the uniformity of the first voltage ASN in the signal channel ACH. The end of an auxiliary line ALX can be directly connected to the first pins APIN or directly connected to a first line AL, as long as the auxiliary line ALX can maintain an electrical connection between two adjacent pixel rows ROW.

In an example, the auxiliary lines ALX may extend along the second direction DB. Of course, some or all of the auxiliary lines ALX can also be polylines or curves. In an example, in the same signal channel ACH, two first lines AL which are adjacent along the second direction DB are electrically connected through an auxiliary line ALX.

In an example, the end of an auxiliary line ALX is electrically connected to the midpoint of a first line AL.

Of course, in other implementations of the present disclosure, even if the signal channel ACH includes a plurality of pixel rows ROW, the light-emitting panel PNL may not be provided with the auxiliary line ALX.

The second pins BPIN of the inorganic light-emitting diodes LD in a pixel column COL are connected to one or more second lines BL, and the second lines BL are used to apply the second voltage BSN. If there are multiple inorganic light-emitting diodes LD located in the same pixel column COL and in the same signal channel ACH, the second pins BPIN of the multiple inorganic light-emitting diodes LD are respectively connected to different second lines BL. In this way, the inorganic light-emitting diode LD electrically connected to each second line BL can be located in one signal channel. Accordingly, each inorganic light-emitting diode LD can be addressed and independently controlled, thereby enabling the light-emitting panel PNL to achieve local dimming. When the second pins BPIN are anode pins, the second voltage BSN is the driving voltage signal; when the second pins BPIN are cathode pin, the second voltage BSN is the reference voltage signal.

In an example, the first pins APIN are anode pins, the first lines AL are anode lines used to apply the driving voltage signal; the second pins BPIN are cathode pins, and the second lines BL are cathode lines used to apply the reference voltage signal.

In an embodiment of the present disclosure, referring to FIG. 8, a signal channel ACH includes one pixel row ROW. The second pin BPIN of each inorganic light-emitting diode LD in the pixel column COL is connected to the same second line BL. In this way, when the first voltage ASN is applied on the signal channel ACH and the second voltage BSN is applied on the second line BL, the inorganic light-emitting diode LD at the intersection of the signal channel ACH and the second line BL can emit light under the driving of the first voltage ASN and the second voltage BSN.

Referring to FIGS. 8 and 9, the second lines BL extend in the second direction DB, the same pixel column COL is connected to the same second line BL, and the orthographic projection of the second line BL overlaps with the orthographic projections of the inorganic light-emitting diodes in at least one pixel column COL. Specifically, the second line BL is located between the orthographic projections of two first pins APIN of an inorganic light-emitting diode LD.

In an example, a second line BL may extend straightly along the second direction DB and passes through gaps between two first pins APIN of a plurality of inorganic light-emitting diodes LD in sequence. The second line BL overlaps with second pins BPIN electrically connected with the second line BL, and the line width of the second line BL at an overlap position (indicated by a black dot in FIG. 8) where the second line BL overlaps with a second pin BPIN is greater than the line width at the remaining positions of the second line BL. For example, the line width of the second line BL at the overlap position where the second line BL overlaps with the second pin BPIN is equivalent to the width of the second pin BPIN along the first direction DA. Further, the area of the overlap region between the second line BL and the second pin BPIN is basically equal to the area of the orthographic projection of the second pin BPIN on the substrate. An opening of an insulating layer OCL may expose a surface of the second line BL at the overlap position where the second line BL overlaps with the second pin BPIN, so that the second pin BPIN and the second line BL are electrically connected at the overlap position through a conductive connection structure BND.

Alternatively, the second line BL does not need to be locally widened at the position where the second line BL is connected to a second pin BPI, or the second line BL may be provided with a side branch structure so that the second line BL overlaps with and is connected to the second pin BPIN through the side branch structure.

In an implementation of the present disclosure, referring to FIG. 10, a signal channel ACH includes two adjacent pixel rows ROW. Second pins BPIN of inorganic light-emitting diodes LD in a pixel column COL are connected to two second lines BL, respectively. Two inorganic light-emitting diodes LD located in the same signal channel ACH in the same pixel column COL are connected to two different second lines BL, respectively. The two second lines BL pass through the regions where the inorganic light-emitting diodes LD are located by passing through the wiring regions between two first pins APIN of the inorganic light-emitting diodes LD.

Referring to FIGS. 10 and 11, second lines BL extend in the second direction DB. Inorganic light-emitting diodes LD in the same pixel column COL are connected to two different second lines BL, respectively. The orthographic projection of a second line BL overlaps with an inorganic light-emitting diode LD in at least one pixel column COL. Referring to the example of FIG. 11, when two second lines BL need to pass through a pixel row ROW, the two second lines BL can pass between two first pins APIN of an inorganic light-emitting diode LD. That is, the two second lines BL are located between the orthographic projections of the two first pins APIN of the inorganic light-emitting diode LD.

Referring to FIG. 10, in an example, two second lines BL may extend in the second direction DB as a whole, but may be partially bent to avoid second pin(s) BPIN that does not need to be electrically connected. For example, when a second line BL needs to be electrically connected to a second pin BPIN of an inorganic light-emitting diode LD, the second line BL may overlap with the second pin BPIN and may be electrically connected to the second pin BPIN through a conductive connection structure BND. When the second line BL does not need to be electrically connected to the second pin BPIN of the inorganic light-emitting diode LD, the second line BL may be bent to bypass the second pin BPIN to avoid a defect of short circuit which occurs between the second line BL and the second pin BPIN. Alternatively, in another example, the second line BL may not avoid the second pin BPIN that does not need to be electrically connected, and the insulating layer OCL may cover the second line BL to realize insulation between the second line BL and the second pin BPIN that does not need to be electrically connected. In other words, when insulation is required between a second line BL and a second pin BPIN, the second line BL may overlap with the second pin BPIN, but the second line BL needs to be isolated from the second pin BPIN by the insulating layer OCL to insulate each other. In this way, each second line BL may extend straightly along the second direction DB, or extend substantially straightly along the second direction DB.

Referring to FIG. 10, in an example, two adjacent inorganic light-emitting diodes LD in the same pixel column COL may be connected to different second lines BL respectively. For example, an even-numbered inorganic light-emitting diode LD is connected to a second line BL. line BL, and an odd-numbered inorganic light-emitting diode LD is connected to another second line BL. This facilitates the driving and debugging of the light-emitting panel PNL.

In an example, the line width (shown as a black dot in FIG. 10) of a second line BL at the overlap position where the second line BL overlaps with a second pin BPIN which is electrically connected to the second line BL is larger than the line width at the remaining positions of the second line BL. For example, the line width of the second line BL at the overlap position where the second line BL overlaps with the second pin BPIN which is electrically connected to the second line BL is equivalent to the width of the second pin BPIN along the first direction DA. Further, the area of the overlap region between the second line BL and the second pin BPIN which is electrically connected to the second line BL is basically equal to the area of the orthographic projection of the second pin BPIN on the base substrate. Alternatively, the second line BL does not need to be locally widened at the position where the second line BL is connected to the second pin BPI, or the second line BL may be provided with a side branch structure and may overlap with and be electrically connected to the second pin BPIN through the side branch structure.

In an implementation of the present disclosure, referring to FIGS. 12 and 13, a signal channel ACH includes three adjacent pixel rows ROW. Second pins BPIN of inorganic light-emitting diodes LD in a pixel column COL are connected to three second lines BL, respectively. The three second lines BL pass through regions where the inorganic light-emitting diodes LD are located by passing through the wiring regions between two first pins APIN of the inorganic light-emitting diodes LD.

Referring to FIG. 12 and FIG. 13, a second line BL extends in the second direction DB and needs to overlap with a part of the pixel rows ROW. In this situation, the second line BL may pass through a gap between two first pins APIN of an inorganic light-emitting diode LD. Referring to the example of FIG. 13, when the three second lines BL all overlap with a pixel row ROW, the three second lines BL may pass between two first pins APIN of an inorganic light-emitting diode LD in the pixel row ROW. That is, the three second lines BL are located between the orthographic projections of the two first pins APIN of the inorganic light-emitting diode LD.

Referring to FIG. 12, in an example, the three second lines BL may extend as a whole along the second direction DB, but may be partially bent to avoid a second pin BPIN that does not need to be electrically connected. For example, when a second line BL needs to be electrically connected to a second pin BPIN of an inorganic light-emitting diode LD, the second line BL may overlap with the second pin BPIN and may be electrically connected to the second pin BPIN through a conductive connection structure BND. When the second line BL does not need to be electrically connected to the second pin BPIN of the inorganic light-emitting diode LD, the second line BL may be bent to bypass the second pin BPIN to avoid a defect of a short circuit which occurs between the second line BL and the second pin BPIN.

Alternatively, in another example, the second line BL may not avoid the second pin BPIN that does not need to be electrically connected, and the insulating layer OCL may cover the second line BL to realize insulation between the second line BL and the second pin BPIN that does not need to be electrically connected to the second line BL. In other words, when insulation is required between a second line BL and a second pin BPIN, the orthographic projection of the second line BL on the substrate may overlap with the orthographic projection of the second pin BPIN on the substrate, but the second line BL and the second pin BPIN are insulated from each other. For example, the insulating layer OCL may be used to electrically isolate the second line BL from the second pin BPIN. In this way, the second lines BL may extend straightly along the second direction DB, or extend substantially straightly along the second direction DB.

Referring to FIG. 12, in an example, inorganic light-emitting diodes LD in the same pixel column COL may be periodically connected to three second lines BL in sequence. for example, the 3N-th (N is 0 or a positive integer) inorganic light-emitting diode LD is connected to the first second line BL, the (3N+1)-th inorganic light-emitting diode LD is connected to the second second line BL, and the (3N+1)-th inorganic light-emitting diode LD is connected to the second second line BL, and the (3N+2)-th inorganic light-emitting diode LD is connected to the third second line BL. This facilitates the driving and debugging of the light-emitting panel PNL.

In an example, the line width (shown as a black dot in FIG. 12) of a second line BL at the overlap position where the second line BL overlaps with a second pin BPIN electrically connected to the second line BL is larger than the line width of the second line BL at the remaining positions. For example, the line width of the second line BL at the overlap position where the second line BL overlaps with the second pin BPIN electrically connected to the second line BL is equivalent to the width of the second pin BPIN along the first direction DA. Further, the area of the overlap region between the second line BL and the second pin BPIN electrically connected to the second line BL is basically equal to the area of the orthographic projection of the second pin BPIN on the base substrate. Alternatively, the second line BL does not need to be locally widened at the position where the second line BL is connected to the second pin BPI, or the second line BL may be provided with a side branch structure, and the second line BL may overlap with and be connected to the second pin BPIN through the side branch structure.

In an implementation of the present disclosure, referring to FIG. 4, the number of second pins BPIN is two and they are electrically connected within an inorganic light-emitting diode LD. In this way, a second line BL is electrically connected to any one of the second pin BPINs, and can be electrically connected to the inorganic light-emitting diode LD. Also, a line can also be set between the two second pins BPIN of the inorganic light-emitting diode LD. In this way, the wiring flexibility of the light-emitting panel PNL is further improved. Optionally, at least part of the second line BL passes through the region where the inorganic light-emitting diode LD is located by passing between the two second pins BPIN.

In an example, referring to FIG. 14, inorganic light-emitting diodes LD in a pixel column COL need to be electrically connected to two second lines BL. The two second lines BL can pass between two second pins BPINs of the inorganic light-emitting diodes LD, and during the passing, the second lines BL are electrically connected to second pin(s) BPIN that need to be electrically connected. For example, a second line BL is electrically connected to a second pin BPIN by setting up a side branch structure. In this way, the two second lines BL can extend straightly side by side, which can not only simplify the wiring manner of the second lines BL, but also prevent the second lines BL from overlapping with second pin(s) BPIN that does (d) not need to be electrically connected to the second lines BL.

The above-mentioned implementations of the present disclosure are described by taking an example where the number of first pins APIN of an inorganic light-emitting diode LD is two. It can be understood that when necessary, an inorganic light-emitting diode LD can also be provided with three or more first pins APIN, and the first pins APIN remain electrically interconnected inside the inorganic light-emitting diode LD.

Correspondingly, the above-mentioned implementations of the present are described by taking an example where the number of second pins BPIN of an inorganic light-emitting diode LD is one or two. It can be understood that when necessary, an inorganic light-emitting diode LD can also be provided with three or more second pins BPIN, and the second pins BPIN remain electrically interconnected inside the inorganic light-emitting diode LD.

In the light-emitting panel PNL according to the implementations of the present disclosure, an inorganic light-emitting diode LD forms an electrical path under the driving of both the first voltage ASN provided by the first line AL and the second voltage BSN provided by the second line BL, and emits light. Signal source(s) that provides (provide) the first voltage ASN and the second voltage BSN may be set on the light-emitting panel PNL, or may be located outside the light-emitting panel PNL.

In the examples of FIGS. 15 to 18, a possible way is illustrated in which the signal sources of the first voltage ASN and the second voltage BSN are located outside the light-emitting panel PNL. In FIGS. 15 to 17, horizontal bar patterns are used to illustrate pixel rows ROW, and vertical bar patterns are used to illustrate pixel columns COL. It can be understood that an intersection of a horizontal bar pattern and a vertical bar pattern represents an inorganic light-emitting diode LD located in the pixel row ROW and pixel column COL. In FIGS. 15 to 17, horizontal thick dotted lines represent first lines AL used to electrically connect inorganic light-emitting diodes LD in the pixel rows ROW. In FIGS. 15 to 17, a thick solid lines continuously pass through pixel columns COL, this only indicates that the first lines AL electrically connect first pins APIN in a pixel row ROW, but does not mean that the number of the first lines AL is one and the one first line directly passes through respective pixel columns COL. For a specific layout diagram of the first lines AL in a pixel row ROW, please refer to FIG. 8, FIG. 10, FIG. 12 or FIG. 14, or use other methods in the description of the first lines AL. In FIGS. 15 to 17, vertical thick solid lines represent second lines BL used to maintain electrical connection of the inorganic light-emitting diodes LD in the pixel columns COL. Multiple second lines located in a pixel column COL BL only mean that inorganic light-emitting diodes LD in pixel column COL are respectively connected to multiple second lines BL, but does not mean that a certain inorganic light-emitting diode LD in the pixel column COL is connected to multiple second lines BL at the same time.

Referring to the examples of FIGS. 15 to 18, in some implementations of the present disclosure, the light-emitting panel PNL may include first pads APAD and first interconnect lines ATRL that correspond one-to-one to respective signal channels ACH, and include second pads BPAD and second interconnect lines BTRL that correspond one-to-one to respectively second lines BL. At least one of the first lines AL for the signal channel ACH is electrically connected to a corresponding first pad APAD through a corresponding first interconnect line ATRL. A second line BL and a corresponding second pad BPAD are electrically connected through a corresponding second interconnect line BTRL. In this way, the first voltage ASN applied on a first pad APAD by a signal source can be applied on inorganic light-emitting diode(s) LD of a signal channel ACH through a first interconnect line ATRL. The second voltage BSN applied on a second pad BPAD by a signal source can be loaded on inorganic light-emitting diode(s) LD connected to a second line BL through a second interconnect line BTRL.

In an example, the light-emitting panel PNL can be electrically connected to the control circuit board. The control circuit board is provided with a light board control chip. The light board control chip can apply the first voltage ASN to the first pads APAD and apply the second voltage BSN to the second pads BPAD through the control circuit board. The light board control chip can control the timing of applying signals to the first pads APAD and the second pads BPAD, thereby controlling the timing of the operation of the inorganic light-emitting diodes LD on the light-emitting panel PNL, so that the pixel rows ROW in the light-emitting control region CA can work one by one or pixel columns COL work one by one. Further, the control circuit board may be a flexible circuit board, or the control circuit board and the light-emitting panel PNL may be bonded and connected through a flexible circuit board. Alternatively, the light board control chip and the control circuit board as a whole can also be realized by chip-on-film (COF).

In some examples, at least one of the second interconnect lines BTRL or at least one of the first interconnect lines ATRL includes multiple sections of interconnect sub-lines arranged in the same layer as the first lines AL, and two adjacent interconnect sub-lines are electrically connected through a jumper resistor BRE arranged in the same layer as the inorganic light-emitting diodes LD. In other words, when other line(s), that does (do) not have an electrical connection relationship, exists (exist) between a first pad APAD and a first line AL to be electrically connected, the connection can be achieved through a jumper resistor BRE. For example, a first interconnect line ATRL includes interconnect sub-lines located in the metal wiring layer WWL, and the interconnect sub-lines are electrically connected through a jumper resistor BRE located in the electronic element layer EEL. Similarly, when there are other lines that do not have an electrical connection relationship between a second pad BPAD and a second line BL to be electrically connected, the second interconnect line BTRL can be bridged by a jumper resistor BRE. The second interconnect line BTRL includes interconnect sub-lines located in the metal wiring layer WWL, and the interconnect sub-lines are electrically connected through a jumper resistor BRE located in the electronic element layer EEL.

In the present disclosure, a jumper resistor BRE can realize the electrical connection of two lines that are located in the same layer but unable to be connected by direct contact. The jumper resistor BRE has two bonding pins that are electrically interconnected within the jumper resistor BRE, and the resistance between the two bonding pins is substantially zero. In this way, the jumper resistor BRE can be respectively bonded and connected to adjacent two ends of a disconnected line to maintain the electrical continuity of the line. Further, a metal connection portion is provided inside the jumper resistor BRE, for example, an aluminum connection portion or a copper connection portion is provided inside the jumper resistor BRE, and the two bonding pins are electrically connected through the metal connection portion. The metal connection portion can be protected and packaged by an insulating layer, to avoid a defect of a short circuit between the metal connection portion and other parts of the light-emitting panel PNL. The jumper resistor BRE can be disposed in the electronic element layer EEL and connected to the light-emitting panel PNL through bonding. Since only the first interconnect line(s) ATRL or the first interconnect line(s) ATRL need to be bridged, and neither the first line(s) AL nor the second line(s) BL needs to be bridged, the number of jumper resistors BRE is greatly reduced, and this does not lead to a significant increase in cost and production cycle time.

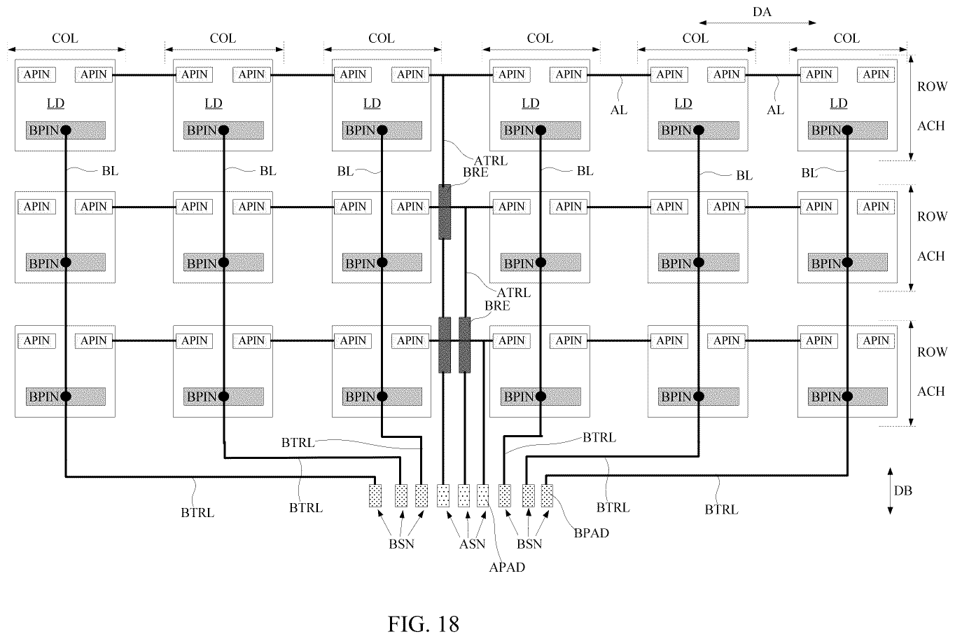

In an example, referring to FIG. 15 and FIG. 18, the light-emitting panel PNL may include only one light-emitting control region CA; each signal channel ACH includes only one pixel row ROW, and inorganic light-emitting diodes LD in each pixel column COL are connected to only one second line BL. In this way, each signal channel ACH needs to be electrically connected to a corresponding first pad APAD through a corresponding first interconnect line ATRL, and each second line BL needs to be electrically connected to a corresponding second pad BPAD through a corresponding second interconnect line BTRL. Referring to FIGS. 15 and 18, when there is another signal channel ACH (which can be called an intermediate signal channel in the present disclosure) between a signal channel ACH and a first pad APAD, the first interconnect line ATRL corresponding to the signal channel ACH needs to pass through respective intermediate signal channel(s). In this case, the first interconnect line ATRL can hop over first line(s) AL of respective intermediate signal channel(s) through jumper resistor(s) BRE.

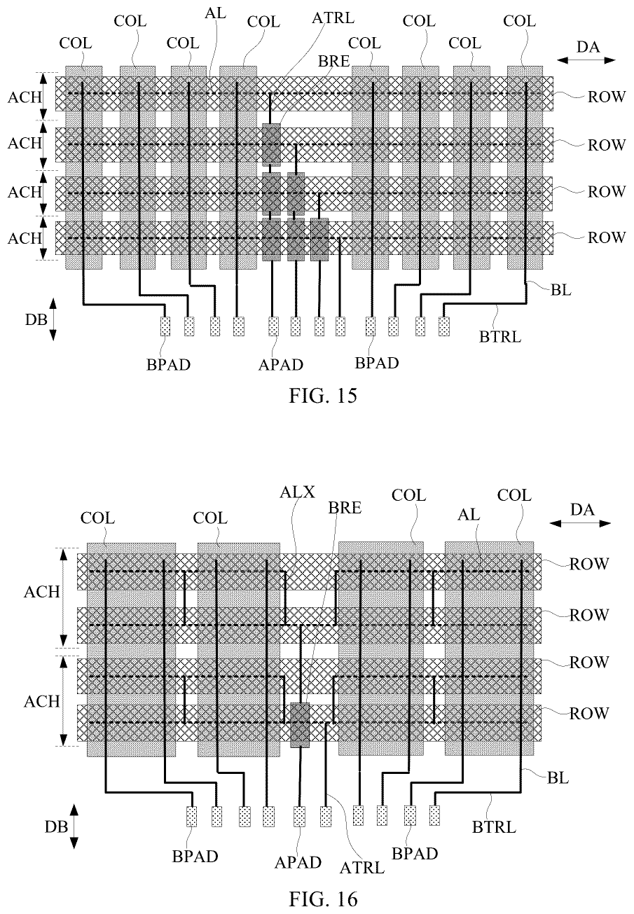

In an example, referring to FIG. 16, the light-emitting panel PNL may include only one light-emitting control region CA; each signal channel ACH includes only two pixel rows ROW, and inorganic light-emitting diodes LD in each pixel column COL are connected to two A second line BL. In this way, each signal channel ACH needs to be electrically connected to a corresponding first pad APAD through a corresponding first interconnect line ATRL, and each second line BL needs to be electrically connected to a corresponding second pad BPAD through a corresponding second interconnect line BTRL. Referring to FIG. 16, when there is another signal channel ACH (which may be called an intermediate signal channel in the present disclosure) between a signal channel ACH and a first pad APAD, the first interconnect line ATRL corresponding to the signal channel ACH needs to pass through respective intermediate signal channel(s). In this situation, the first interconnect line ATRL can cross first line(s) AL of respective intermediate signal channel(s) through jumper resistor(s) BRE.

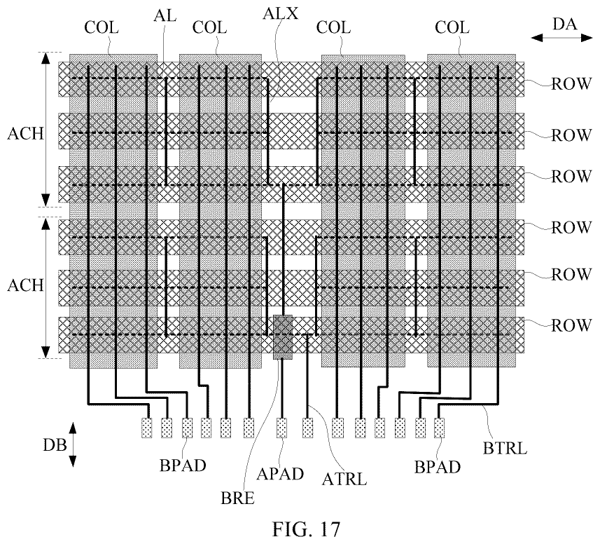

In an example, the light-emitting panel PNL may include only one light-emitting control region CA; each signal channel ACH includes m pixel rows ROW, and inorganic light-emitting diodes LD in each pixel column COL are connected to m second lines BL, as shown in FIG. 17, m=3. In this way, each signal channel ACH needs to be electrically connected to a corresponding first pad APAD through a corresponding first interconnect line ATRL, and each second line BL needs to be electrically connected to a corresponding second pad BPAD through a corresponding second interconnect line BTRL. Referring to FIG. 17, when there is another signal channel ACH (which may be called an intermediate signal channel ACH in the present disclosure) between a signal channel ACH and a first pad APAD, the first interconnect line ATRL corresponding to the signal channel ACH needs to pass through respective intermediate signal channel(s) ACH. In this situation, the first interconnect line ATRL can cross first line(s) AL of respective intermediate signal channel(s) ACH through jumper resistor(s) BRE.

In the examples of FIGS. 15 to 18, the light-emitting panel PNL having one light-emitting control region CA is only taken as an example. It can be understood that when the light-emitting panel PNL is provided with multiple light-emitting control regions CA, each light-emitting control region CA may be provided with first pads APAD, first interconnect lines ATRL, second pads BPAD and second interconnect lines BTRL to respectively receive and transmit the first voltage ASN and the second voltage BSN required by each light-emitting control region CA. Alternatively, the first pads APAD and the second pads BPAD of the multiple light-emitting control regions CA can also be concentrated in one or more places to facilitate centralized bonding of the control circuit board.

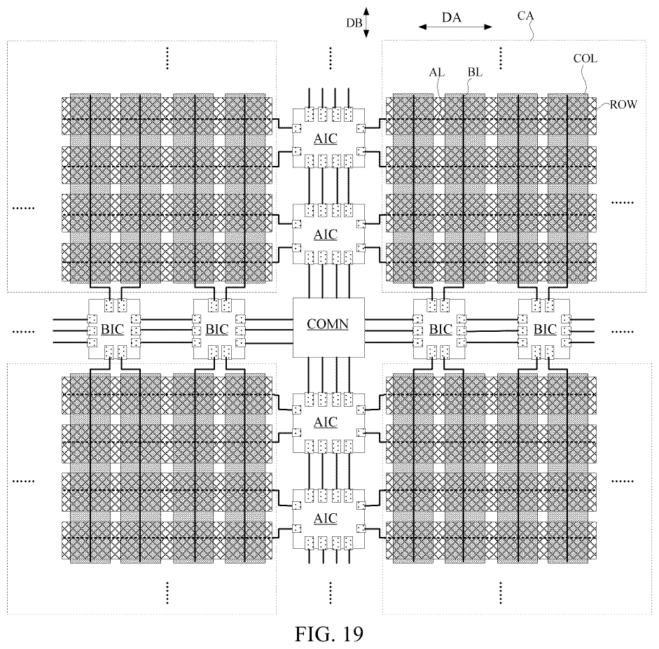

In the examples of FIG. 19 to FIG. 21, a possible way in which the signal sources of the first voltage ASN and the second voltage BSN are located on the light-emitting panel PNL is illustrated. In FIG. 19 to FIG. 21, horizontal bar patterns are used to illustrate pixel rows ROW, and vertical bar patterns are used to illustrate pixel columns COL. It can be understood that an intersection of a horizontal bar pattern and a vertical bar pattern represents an inorganic light-emitting diode LD located in the pixel row ROW and pixel column COL. In FIGS. 19 to 21, horizontal thick dotted lines represent first lines AL used to electrically connect inorganic light-emitting diodes LD in the pixel rows ROW. In FIGS. 19 to 21, thick solid lines continuously passing through the pixel columns COL is only used to indicate that the first lines AL keep the first pins APIN in the pixel rows ROW electrically continuous, but does not mean that the number of the first lines AL is one and the one first line directly passes through respective pixel columns COL. For a specific layout diagram of the first lines AL in the pixel rows ROW, please refer to FIG. 8, FIG. 10, FIG. 12 or FIG. 14, or use other methods in the description of the first lines AL. In FIGS. 19 to 21, vertical thick solid lines represent second lines BL used to maintain electrical connection of inorganic light-emitting diodes LD in the pixel columns COL. Multiple second lines located in a pixel column COL BL only mean that the inorganic light-emitting diodes LD in the pixel column COL are respectively connected to multiple second lines BL, but does not mean that a certain inorganic light-emitting diode LD in the pixel column COL is connected to multiple second lines BL at the same time.

Referring to FIGS. 19 to 21, the light-emitting panel PNL further includes a plurality of second control chips BIC arranged along the first direction DA, and a plurality of first control chips AIC arranged along the second direction DB. A first control chip AIC has one or more first output pins AOUT. A first output pin AOUT is used to apply the first voltage ASN on a first line AL in a corresponding signal channel under control of the first control chip AIC. A second control chip BIC has one or more second output pins BOUT. A second output pin BOUT is used to apply the second voltage BSN on a corresponding second line BL under control of the second control chip. In other words, the light-emitting panel PNL may be provided with first control chips AIC for outputting the first voltage ASN and second control chips BIC for outputting the second voltage BSN. Each signal channel ACH receives the first voltage ASN in an orderly manner under control of a first control chip AIC, and each second line BL receives the second voltage BSN in an orderly manner under control of a second control chip BIC.

In an implementation of the present disclosure, referring to FIGS. 19 to 21, a signal interface COMN can also be provided on the light-emitting panel PNL. The signal interface is connected to the first control chips AIC and the second control chips BIC to provide the required signals and voltages to the first control chips AIC and the second control chips BIC. For example, the light-emitting control component can be connected to the signal interface to apply the required voltage and driving data Data to a first control chip AIC through the signal interface, and to apply the required voltage and driving data Data to a second control chip BIC through the signal interface. The first control chip AIC controls the first output pin(s) AOUT to output the first voltage ASN and the timing of outputting the first voltage ASN according to the received driving data Data and the voltage; the second control chip BIC controls the second output pin(s) BOUT to output the second voltage BSN and the timing of outputting the second voltage BSN according to the received driving data Data and the voltage.

In an example, the light-emitting control component may have a main control chip and a signal output port. The signal output port of the light-emitting control component may be connected to the signal interface COMN of the light-emitting panel PNL, for example, by plugging. The signal generated by the main control chip is applied to the first control chips AIC and the second control chips BIC through the signal interface COMN.

In an example, referring to FIGS. 19 to 21, the light-emitting panel PNL has four light-emitting control regions CA, and the four light-emitting control regions CA are distributed in a 2×2 distribution. The first control chips AIC can be disposed between two adjacent light-emitting control regions CA along the first direction DA, and are capable of simultaneously applying the first voltage ASN to the signal channels ACH in the two adjacent light-emitting control regions CA respectively. For example, a first control chip AIC may have two groups of first output pins AOUT respectively corresponding to two adjacent light-emitting control regions CA, and each group of first output pins AOUT includes one or more first output pins AOUT, each group of first output pins AOUT is used to apply the first voltage ASN to the signal channel(s) ACH in the corresponding light-emitting control region CA, and one first output pin AOUT is used to apply the first voltage ASN to one signal channel ACH. In this way, the number of required first control chips AIC can be significantly reduced. The second control chips BIC can be disposed between two adjacent light-emitting control regions CA along the second direction DB, and are capable of simultaneously applying the second voltage BSN to the second lines BL in the two adjacent light-emitting control regions CA respectively. For example, the second control chip BIC may have two groups of second output pins BOUT respectively corresponding to two adjacent light-emitting control regions CA, and each group of second output pins BOUT includes one or more second output pins BOUT, each group of second output pins BOUT is used to apply the second voltage BSN to the second lines BL in the corresponding light-emitting control region CA, and one second output pin BOUT is used to apply the second voltage BSN to one second line BL. In this way, the number of required second control chips BIC can be significantly reduced.

Further, the signal interface COMN can be located in the middle of the light-emitting panel PNL. The second control chips BIC are provided on both sides of the signal interface COMN in the first direction DA, and the first control chips AIC are provided on both sides of the signal interface COMN in the second direction DB. In this way, the signals on the signal interface COMN are applied to each first control chip AIC and second control chip BIC in a timely manner, which in turn helps improve the refresh rate of the inorganic light-emitting diodes LD in each light-emitting control region CA.

In an example, the signal interface COMN is disposed on a non-light-emitting surface of the light-emitting panel PNL.

In an example, referring to FIG. 19, in each light-emitting control region CA, each signal channel ACH includes only one pixel row ROW, and the inorganic light-emitting diodes LD in each pixel column COL are only connected to one second line BL. In this way, at least one first line AL of each signal channel ACH can be electrically connected to a first output pin AOUT of an adjacent first control chip AIC, and each second line BL can be electrically connected to a second output pin BOUT of an adjacent second control chip BIC. In the example of FIG. 19, each first control chip AIC includes two groups of first output pins AOUT, and each group of first output pins AOUT may include two first output pins AOUT, so that each first control chip The chip AIC can drive four pixel rows ROW, which can significantly reduce the number of first control chips AIC. In other examples of the present disclosure, the number of the first output pins AOUT of each first control chip AIC may be more or less, for example, the number may be two or six, as long as the requirements of size and number of the first control chips AIC can be met. In the example of FIG. 19, each second control chip BIC includes two groups of second output pins BOUT, and each group of second output pins BOUT may include two second output pins BOUT, so that each second control chip BIC can drive four pixel columns COL, which can greatly reduce the number of second control chips BIC. In other examples of the present disclosure, the number of the second output pins BOUT of each second control chip BIC may be more or less, for example, it may be two or six, as long as the requirements of size and number of the second control chips BIC can be met.

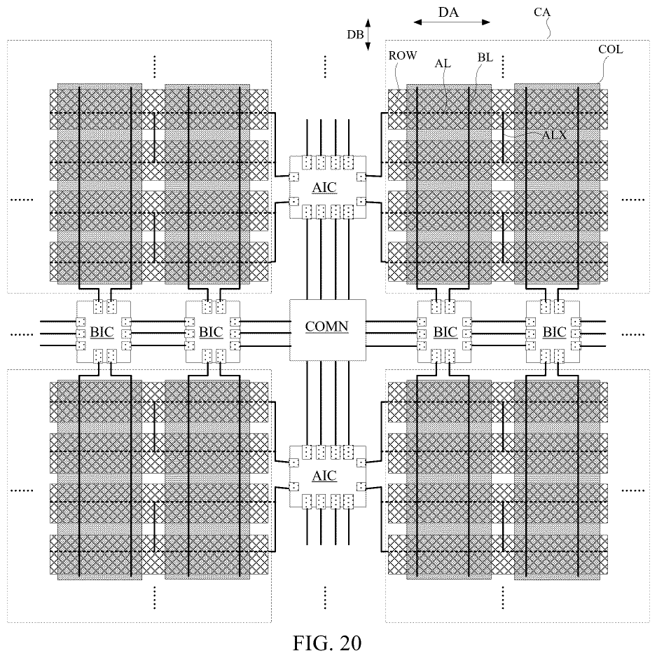

In an example, referring to FIG. 20, in each light-emitting control region CA, each signal channel ACH includes two pixel rows ROW, and the inorganic light-emitting diodes LD in each pixel column COL are respectively connected to two second line BL. In this way, at least one first line AL of each signal channel ACH can be electrically connected to a first output pin AOUT of an adjacent first control chip AIC, and each second line BL can be electrically connected to a second output pin BOUT of an adjacent control chip BIC. In the example of FIG. 20, each first control chip AIC includes two groups of first output pins AOUT, and each group of first output pins AOUT may include two first output pins AOUT, so that each first control chip AIC can drive four signal channels ACH, that is, each first control chip AIC can drive 8 pixel rows ROW, which can greatly reduce the number of the first control chips AIC. In other examples of the present disclosure, the number of the first output pins AOUT of each first control chip AIC may be more or less, for example, it may be two or six, as long as the requirements of size and number of the first control chips AIC can be met. In the example of FIG. 20, each second control chip BIC includes two groups of second output pins BOUT, and each group of second output pins BOUT may include two second output pins BOUT, so that each second control chip BIC can drive four second lines BL, which can greatly reduce the number of second control chips BIC. Further, each second control chip BIC can drive two pixel columns COL, that is, each second control chip BIC can drive two pixel columns COL in two light-emitting control regions CA respectively, and two second lines BL electrically connected to each pixel column COL are driven by the same second control chip BIC. In other examples of the present disclosure, the number of the second output pins BOUT of each second control chip BIC may be more or less, for example, it may be two or six, as long as the requirements of size and number of the second control chips BIC can be met. In other examples of the present disclosure, for a part of the pixel columns COL, two second lines BL electrically connected to a pixel column COL can be driven by two different second control chips BIC.

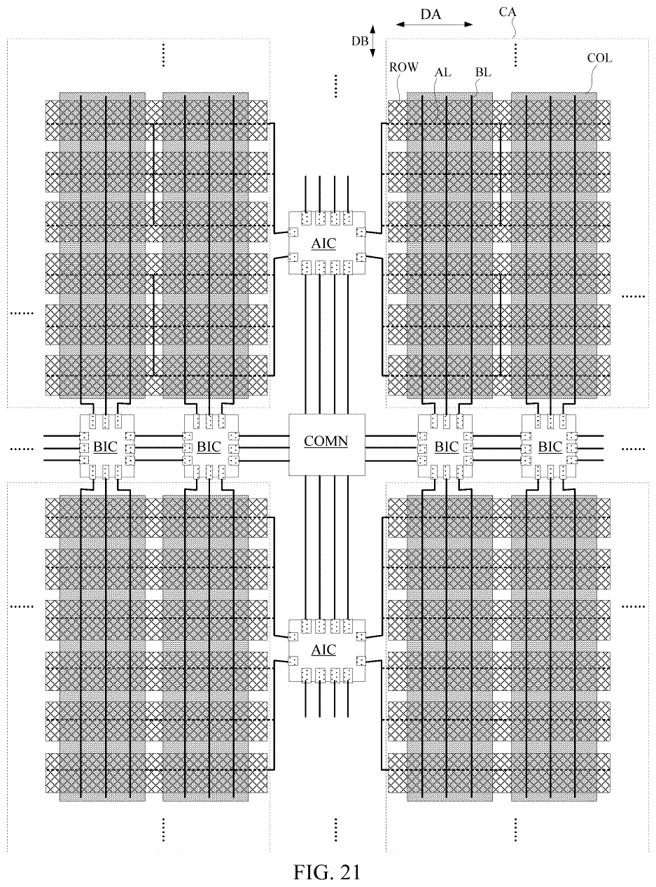

In an example, referring to FIG. 21, in each light-emitting control region CA, each signal channel ACH includes three pixel rows ROW, and inorganic light-emitting diodes LD in each pixel column COL are connected to three second lines BL, respectively. In this way, at least one first line AL of each signal channel ACH can be electrically connected to a first output pin AOUT of an adjacent first control chip AIC, and each second line BL can be electrically connected to a second output pin BOUT of an adjacent control chip BIC. In the example of FIG. 21, each first control chip AIC includes two groups of first output pins AOUT, and each group of first output pins AOUT may include two first output pins AOUT, so that each first control chip AIC can drive four signal channels ACH, that is, each first control chip AIC can drive 12 pixel rows ROW, which can greatly reduce the number of the first control chips AIC. In other examples of the present disclosure, the number of the first output pins AOUT of each first control chip AIC may be more or less, for example, the number may be two or six, as long as the requirements of size and number of the first control chips AIC can be met. In the example of FIG. 21, each second control chip BIC includes two groups of second output pins BOUT, and each group of second output pins BOUT may include three second output pins BOUT, so that each second control chip can drive six second lines BL, which can greatly reduce the number of second control chips BIC. Further, each second control chip BIC can drive two pixel columns COL, that is, each second control chip

BIC drive two pixel columns COL in two light-emitting control regions CA respectively, and three second lines BL electrically connected to each pixel column COL are driven by the same second control chip BIC. In other examples of the present disclosure, the number of the second output pins BOUT of each second control chip BIC may be more or less, for example, the number may be two or four, as long as the requirements of size and number of the second control chips BIC can be met. In other examples of the present disclosure, for a part of pixel columns COL, the three second lines BL electrically connected to the pixel column COL can also be driven by two different second control chips BIC.

In the examples of FIGS. 19 to 21, taking the light-emitting panel PNL having four light-emitting control regions CA as an example, the implementation of providing the first control chips AIC and the second control chips BIC on the light-emitting panel PNL is explained and illustrated. It can be understood that in other embodiments of the present disclosure, the light-emitting panel PNL may have more or fewer light-emitting control regions CA, for example, one light-emitting control region CA or eight light-emitting control regions CA may be provided.

In the examples of FIGS. 19 to 21, the implementation of providing the first control chips AIC and the second control chips BIC on the light-emitting panel PNL is explained and illustrated by taking the situation where the signal interface COMN is provided on the light-emitting panel PNL and the light-emitting control component applies the required signals and voltages respectively to the first control chips AIC and the second control chips BIC through the signal interface COMN as an example. It can be understood that in some other embodiments of the present disclosure, the signal interface COMN may not be provided on the light-emitting panel PNL, and the required signals and voltages may be applied to the first control chips AIC and the second control chips BIC through other feasible methods. In an implementation of the present disclosure, the light-emitting control component can be bonded and connected to the light-emitting panel PNL, and then apply the required signals and voltages to each of the first control chips AIC and the second control chips BIC. For example, the light-emitting control component may include a flexible circuit board. A bonding region is provided on the light-emitting panel PNL. Pads are provided in the bonding region. The pads are electrically connected to the first control chips AIC and the second control chips BIC through lines located in the metal wiring layer WWL. The flexible circuit board in the light-emitting control component can be bonded and connected to the pads of the light-emitting panel PNL, and accordingly apply the signals and voltages to each of the first control chips AIC and the second control chips BIC through the bonding region. In another embodiment of the present disclosure, the light-emitting panel PNL may also be provided with a main control chip and a bonding region. The main control chip is electrically connected to each of the first control chips AIC and the second control chips BIC through lines. The control circuit board can be electrically connected to the bonding region to apply the required signals and voltages to the main control chip. The main control chip can apply the required signals and voltages to the first control chips AIC and the second control chips BIC according to the signals and voltages of the main control circuit board. Of course, some or all of the voltages required by the first control chips AIC and the second control chips BIC can also be provided by the control circuit board without the need for the main control chip.

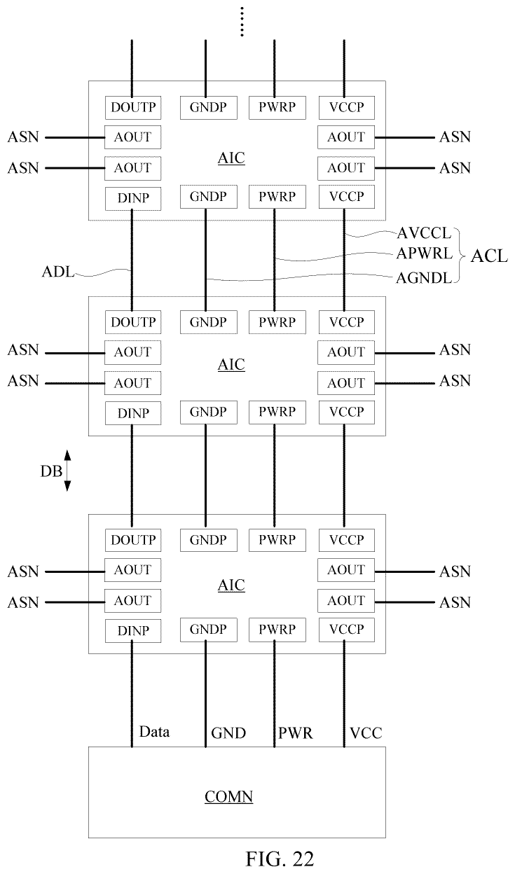

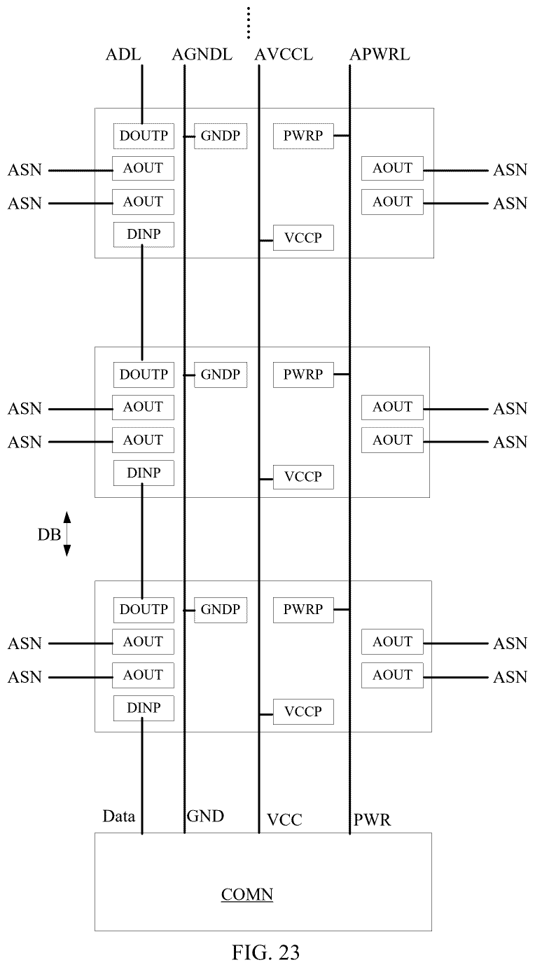

In an implementation of the present disclosure, referring to FIGS. 22 and 23, a first control chip AIC includes a data input pin DINP and a data output pin DOUTP. In two adjacent first control chips AIC, a data output pin DOUTP of one of the first control chips AIC is electrically connected to a data input pin DINP of the other first control chip AIC through a first data line ADL arranged in the same layer as the first line AL. The light-emitting panel PNL further includes a plurality of first power supply lines ACL arranged in the same layer as the first line AL and extending along the second direction DB, and the first power supply lines ACL are used to provide required voltages to the first control chip(s) AIC. In this way, the first control chips AIC can receive the required driving data Data through the data input pins DINP, and receive the voltages provided by the first power supply lines ACL. In this way, a first control chips AIC can output the first voltage ASN through the first output pin AOUT under the control of the received driving data Data. Also, the first control chip AIC can also forward the driving data Data required by other first control chips AIC through the data output pin DOUTP. Further, the data input pin DINP of the first control chip AIC closest to the signal interface COMN is electrically connected to the signal interface COMN through a first data line ADL, so as to receive the driving data Data required by respective first control chips AIC.

For example, in an example, multiple sequentially adjacent first control chips AIC are arranged in cascade, and each of them is pre-configured with address information. The signal interface COMN can send a data packet to the data input pin DINP of a first-level first control chip AIC. The data packet has the driving data Data required by respective cascaded first control chips AIC, and each driving data Data is associated with the address information of a corresponding first control chip AIC. Respective first control chips AIC receive the data packet through data input pins DINP, and forward the data packet through data output pins DOUTP. This allows each cascaded first control chip AIC to receive the data packet. At the same time, the first control chips AIC can obtain the required driving data Data from the data packet according to the address information. Of course, in other implementations of the present disclosure, the first control chips AIC can also use other communication methods or communication protocols to obtain the required driving data Data from the data packet applied by the signal interface COMN. For example, the first control chips AIC do not need to be cascaded. The first control chips AIC can be provided with data pins and the metal wiring layer WWL is provided with a first data line ADL connected to the signal interface COMN. The data pins of multiple first control chips AIC are all electrically connected to the first data line ADL to receive the data packet from the first data line ADL and obtain the required driving data Data from the data packet according to the address information. Or, the first control chips AIC do not need to be cascaded. The data input pin DINP and the data output pin DOUTP of a first control chip AIC are electrically connected inside the first control chip AIC, which allow adjacent multiple first control chips AIC to be able to receive a data packet from the first data line ADL (for example, receive a data packet simultaneously), and obtain the required driving data Data from the data packet according to the address information.

In an implementation of the present disclosure, referring to FIG. 22, a first control chip AIC includes multiple types of power pins. The number of each type of power pins is two and the two power pins are arranged oppositely. Two power pins of the same type are electrically connected inside the first control chip AIC. Among multiple adjacent first control chips AIC, two adjacent power pins of the same type of two adjacent first control chips AIC are electrically connected through a first power supply line ACL. In other words, two adjacent first power supply lines ACL are electrically connected through a first control chip AIC, so that the voltage applied on the first power supply line ACL remains electrically continuous. In this way, the voltage applied by the first power supply line ACL can cross the region where the first control chip AIC is located through the first control chip AIC, which helps the first power supply line ACL avoid other possible lines and helps improve the wiring flexibility of the light-emitting panel PNL.

For example, the first power supply line ACL may include a first reference voltage line AGNDL for applying a reference voltage signal GND, and a first chip power supply line AVCCL for applying a chip power supply voltage VCC. The first control chip AIC may include two reference voltage pins GNDP arranged oppositely along the second direction DB and electrically interconnected inside the first control chip AIC. Two adjacent reference voltage pins GNDP of two adjacent first control chips AIC are electrically connected through a first reference voltage line AGNDL. The reference voltage pin GNDP close to the signal interface COMN (that is, the reference voltage pin GNDP among the multiple first control chips AIC which is closest to the signal interface COMN) of the first control chip AIC closest to the signal interface COMN is electrically connected to the signal interface COMN through a first reference voltage line AGNDL. In this way, the reference voltage signal GND applied by the signal interface COMN to the first reference voltage line AGNDL can be applied to respective first control chips AIC. A first control chip AIC may include two chip power supply voltage pins VCCP arranged oppositely along the second direction DB and electrically interconnected inside the first control chip AIC. Two adjacent chip power supply voltage pins VCCP of two adjacent first control chips AIC are electrically connected through a first chip power supply line AVCCL. The chip power supply voltage pin VCCP of the first-level first control chip AIC close to the signal interface COMN is electrically connected to the signal interface COMN through a first chip power supply line AVCCL. In this way, the chip power supply voltage VCC applied by the signal interface COMN to the first chip power supply line AVCCL can be applied to respective first control chips AIC.

In an example, the first pin APIN is an anode pin, and the first control chip AIC also needs a driving voltage signal PWR. In this case, referring to FIG. 22, the first control chip AIC may include two driving voltage signal pins PWRP that are oppositely arranged along the second direction DB and electrically interconnected inside the first control chip AIC. Two adjacent driving voltage signal pins PWRP of two adjacent first control chips AIC are electrically connected through a driving voltage signal line APWRL. The driving voltage signal pin PWRP closest to the signal interface COMN is electrically connected to the signal interface COMN through a driving voltage signal line APWRL. In this way, the driving voltage signal PWR applied by the signal interface COMN to the driving voltage signal line APWRL can be applied to respective first control chips AIC. When the first control chip AIC works, it can determine the output timing of each first output pin AOUT according to the received driving data Data, and the first output pin AOUT can output the driving voltage signal PWR when outputting.

In an embodiment of the present disclosure, referring to FIG. 23, in a plurality of adjacent first control chips AIC, the same first power supply line ACL is electrically connected to each of the first control chips AIC. For example, the first power supply line ACL may include a first reference voltage line AGNDL for applying a reference voltage signal GND, and a first chip power supply line AVCCL for applying a chip power supply voltage VCC. The first control chip AIC includes a reference voltage pin GNDP and a chip power supply voltage pin VCCP. The first reference voltage line AGNDL is electrically connected to the signal interface COMN, and is electrically connected to the reference voltage pin(s) GNDP of adjacent first control chip(s) AIC. The first chip power supply line AVCCL is electrically connected to the signal interface COMN, and is electrically connected to chip power supply voltage pin(s) VCCP of adjacent first control chip(s) AIC. In this way, the signal interface COMN can apply the reference voltage signal to respective first control chips AIC through the first reference voltage line AGNDL, and apply the chip power supply voltage VCC to respective first control chips AIC through the first chip power supply line AVCCL.

In an example, the first pin APIN is an anode pin, and the first control chip AIC further needs a driving voltage signal PWR. In this case, referring to FIG. 23, the first control chip AIC can also be provided with a driving voltage signal pin PWRP, and the metal wiring layer WWL can be provided with a driving voltage signal line APWRL. The driving voltage signal line APWRL is electrically connected to the signal interface COMN, and is electrically connected to driving voltage signal pin(s) PWRP of adjacent first control chip(s) AIC. In this way, the driving voltage signal PWR applied by the signal interface COMN to the driving voltage signal line APWRL can be applied to respective first control chips AIC. When a first control chip AIC works, it can determine the output timing of each first output pin AOUT according to the received driving data Data, and the first output pin AOUT can output the driving voltage signal PWR when outputting.

It can be understood that pins of a first control chip AIC illustrated in FIG. 22 are not necessarily all the pins of the first control chip AIC. If necessary, the first control chip AIC may also be provided with other pins, and line(s) in the metal wiring layer WWL of the light-emitting panel PNL may be provided, so that these pins are electrically connected to the signal interface COMN. When a newly added line needs to cross other lines in the metal wiring layer WWL, the crossing can be achieved by using the electrical interconnection of the pins in the first control chip AIC or by setting additional jump resistor(s) BRE. For example, when the first control chip AIC needs a clock signal, a clock pin can be provided in the first control chip AIC and a clock line can be provided in the metal wiring layer WWL, so that the signal interface COMN can apply a clock signal to the clock pin through the clock line.

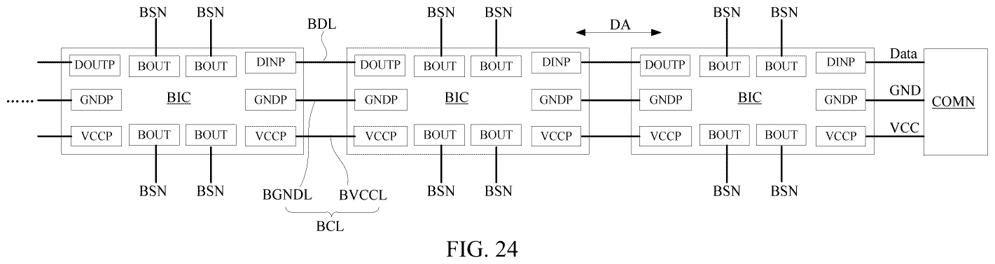

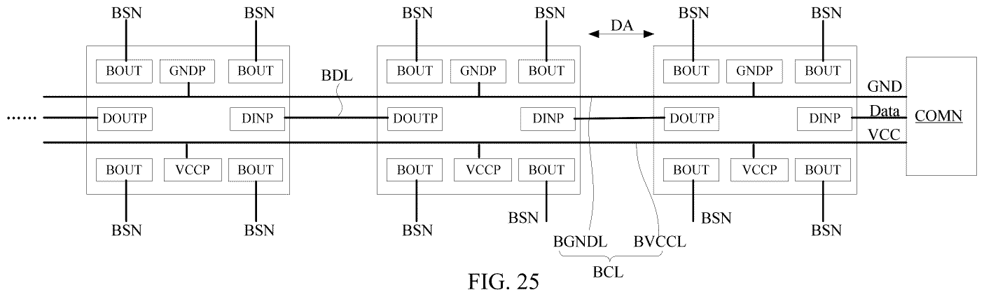

In an implementation of the present disclosure, referring to FIGS. 24 and 25, a second control chip BIC includes a data input pin DINP and a data output pin DOUTP. In two adjacent second control chips BIC, a data output pin DOUTP of one of the second control chips BIC is electrically connected to a data input pin DINP of the other second control chip BIC through a second data line BDL arranged in the same layer as the second line BL. The light-emitting panel PNL further includes a plurality of second power supply lines BCL arranged in the same layer as the second line BL and extending along the first direction DA. The second power supply lines BCL are used to provide the required voltages to the second control chip BIC. In this way, the second control chips BIC can receive the required driving data Data through the data input pin DINP, and receive the voltage provided by the second power supply line BCL. In this way, the second control chip BIC can output the second voltage BSN through the second output pin BOUT under the control of the received driving data Data. Also, the second control chip BIC can also forward the driving data Data required by other second control chips BIC through the data output pin DOUTP. Further, the data input pin DINP of the second control chip BIC closest to the signal interface COMN is electrically connected to the signal interface COMN through a second data line BDL, so as to receive the driving data Data required by respective second control chips BIC.

For example, in an example, multiple adjacent second control chips BIC can be cascaded at one time, and each of the cascaded second control chips BIC is pre-configured with address information. The signal interface COMN can send a data packet to a data input pin DINP of a first-level second control chip BIC. The data packet has the driving data Data required by respective cascaded second control chips BIC, and each driving data Data is associated with a corresponding second control chip BIC. Each second control chip BIC receives the data packet through the data input pin DINP, and forwards the data packet through the data output pin DOUTP; this allows each cascaded second control chip BIC to be able to receive the data packet. At the same time, the second control chip BIC can obtain the required driving data Data from the data packet according to the address information. Of course, in other implementations of the present disclosure, the second control chips BIC can also use other communication methods or communication protocols to obtain the required driving data Data from the data packet applied by the signal interface COMN. For example, the second control chips BIC do not need to be cascaded. A second control chip BIC can be provided with a data pin and the metal wiring layer WWL is provided with a second data line BDL connected to the signal interface COMN. Data pins of multiple adjacent second control chips BIC are all electrically connected to the second data line BDL to receive the data packet from the second data line BDL and obtain the required driving data Data from the data packet according to the address information. For another example, the data input pin DINP and the data output pin DOUTP of a second control chip BIC are electrically connected inside the second control chip BIC, which makes adjacent second data lines BDL electrically connected to each other as a whole. The second control chips BIC can simultaneously receive the data packet from the second data line BDL, and obtain the required driving data Data from the data packet according to the address information.

In an implementation of the present disclosure, referring to FIG. 24, the second control chip BIC includes multiple types of power pins. The number of each type of power pin is two and the two power pins are arranged oppositely along the first direction DA. Two power pins of the same type are electrically connected inside the second control chip BIC. Among multiple adjacent second control chips BIC, two adjacent power pins of the same type of two adjacent second control chips BIC are electrically connected through a second power supply line BCL. In other words, two adjacent second power supply lines BCL are electrically connected through a second control chip BIC, so that the voltage applied on the second power supply lines BCL remains electrically continuous. In this way, the voltage applied by a second power supply lines BCL can cross the region where the second control chip BIC is located through the second control chip BIC, which helps the second power supply line BCL avoid other possible lines and helps improve the wiring flexibility of the light-emitting panel PNL.

For example, the second power supply line BCL may include a second reference voltage line BGNDL for applying a reference voltage signal GND, and a second chip power supply line BVCCL for applying a chip power supply voltage VCC. The second control chip BIC may include two reference voltage pins GNDP arranged oppositely along the first direction DA and electrically interconnected inside the second control chip BIC. Two adjacent reference voltage pins GNDP of two adjacent second control chips BIC are electrically connected to each other through a second reference voltage line BGNDL. The reference voltage pin GNDP closest to the signal interface COMN is electrically connected to the signal interface COMN through a second reference voltage line BGNDL. In this way, the reference voltage signal applied by the signal interface COMN to the second reference voltage line BGNDL can be applied to respective adjacent second control chips BIC. The second control chip BIC may include two chip power supply voltage pins VCCP arranged oppositely along the first direction DA and electrically interconnected inside the second control chip BIC. Two adjacent power supply voltage pins VCCP of two adjacent second control chips are electrically connected to each other through a second chip power supply line BVCCL. The chip power supply voltage pin VCCP closest to the signal interface COMN is electrically connected to the signal interface COMN through a second chip power supply line BVCCL. In this way, the chip power supply voltage VCC applied by the signal interface COMN to the second chip power supply line BVCCL can be applied to respective second control chips BIC.

In an example, the second pin BPIN is a cathode pin. When the second control chip BIC works, it can determine the electrical conduction or electrical cutoff between each second output pin BOUT and the second reference voltage line BGNDL according to the received driving data Data. When electrical conduction occurs between the second output pin BOUT and the second reference voltage line BGNDL, the second line BL connected to the second output pin BOUT is applied with the reference voltage signal as the second voltage BSN; when electrical cutoff occurs between the second output pin BOUT and the second reference voltage line BGNDL, each inorganic light-emitting diode LD connected to the second line BL is electrically disconnected. Further, when the second control chip BIC works, it can also control the magnitude of the current flowing through the second output pin BOUT when electrical conduction occurs between the second output pin BOUT and the second reference voltage line BGNDL, for example, to make inorganic light-emitting diode(s) LD operate at constant current while in the electrical path.

In an implementation of the present disclosure, referring to FIG. 25, in a plurality of adjacent second control chips BIC, the same second power supply line BCL is electrically connected to each of the second control chips BIC. For example, the second power supply line BCL may include a second reference voltage line BGNDL for applying a reference voltage signal, and a second chip power supply line BVCCL for applying a chip power supply voltage VCC. A second control chip BIC includes a reference voltage pin GNDP and a chip power supply voltage pin VCCP. The second reference voltage line BGNDL is electrically connected to the signal interface COMN, and is electrically connected to the reference voltage pin(s) GNDP of adjacent second control chip(s) BIC. The second chip power supply line BVCCL is electrically connected to the signal interface COMN, and is electrically connected to the chip power supply voltage pin(s) VCCP of adjacent second control chip(s) BIC. In this way, the signal interface COMN can apply the reference voltage signal to respective second control chips BIC through the second reference voltage line BGNDL, and apply the chip power supply voltage VCC to respective second control chip(s) BIC through the second chip power supply line BVCCL.

It can be understood that individual pins of a second control chip BIC illustrated in FIGS. 24 and 25 are not necessarily all the pins of the second control chip BIC. If necessary, the second control chip BIC may also be provided with other pins, and line(s) may be provided in the metal wiring layer WWL of the light-emitting panel PNL, so that the pin(s) is (are) electrically connected to the signal interface COMN. When a newly added line needs to cross other lines in the metal wiring layer WWL, the crossing can be achieved by using the electrical interconnection of the pins in the second control chip BIC or by setting additional jump resistor(s) BRE. For example, when the second control chip BIC requires a clock signal, a clock pin can be provided in the second control chip BIC and the metal wiring layer WWL can be provided with a clock line, so that the signal interface COMN can apply a clock signal to the clock pin through the clock line.

An implementation of the present disclosure also provides a backlight module, which includes any of the light-emitting panels described in above implementations of the above light-emitting panels. The backlight module can be a backlight module for a liquid crystal smartphone screen, a backlight module for a smart watch screen, or a backlight module for other types of liquid crystal display devices. Since the backlight module has any of the light-emitting panels described in the above-mentioned implementations of the above light-emitting panels, the backlight module has the same beneficial effects, and thus repeated descriptions are omitted here.

An implementation of the present disclosure also provides a display device, which includes any one of the backlight modules described in the above-mentioned implementations of the backlight module. The display device may be a smartphone screen, a smart watch screen, or other types of display devices. Since the display device has any of the backlight modules described in the above-mentioned implementations of the backlight modules, the display device has the same beneficial effects, and thus repeated descriptions are omitted here.

Other embodiments of the present disclosure will be readily apparent to those skilled in the art from consideration of the specification and practice of the present disclosure. This application is intended to cover any variations, uses, or adaptations of the present disclosure that follow the general principles of the present disclosure and include common knowledge or customary technical means in the technical field that are not disclosed herein. It is intended that the specification and examples should be considered as exemplary only, with a true scope and spirit of the present disclosure being indicated by the appended claims.

1. A light-emitting panel, comprising at least one light-emitting control region, wherein in any one of the at least one light-emitting control region, the light-emitting panel comprises inorganic light-emitting diodes distributed in an array and comprises at least one first line extending along a first direction and at least one second line extending along a second direction;
wherein one of the inorganic light-emitting diodes has a plurality of first pins and at least one second pin, and the plurality of first pins are electrically connected inside the one of the inorganic light-emitting diodes;
wherein a first pin of one of two inorganic light-emitting diodes adjacent along the first direction is electrically connected to an adjacent first pin of the other one of the two inorganic light-emitting diodes through a corresponding first line, the second pin of one of the inorganic light-emitting diodes is electrically connected to a corresponding second line, and the second line passes through a region where the one of the inorganic light-emitting diodes is located by passing between two first pins of the one of the inorganic light-emitting diodes.

2. The light-emitting panel according to claim 1, wherein the number of the plurality of first pins of one of the inorganic light-emitting diodes is two, and the two first pins are arranged along the first direction.

3. The light-emitting panel according to claim 1, wherein:
the light-emitting panel comprises a base substrate, a metal wiring layer, an insulating layer and an electronic element layer that are stacked in sequence,
the metal wiring layer is provided with the at least one first line and the at least one second line,
the insulating layer covers the metal wiring layer and has openings that expose a local region of the first line and an opening that expose a local region of the second line;
the electronic element layer comprises the inorganic light-emitting diodes, the first pins of one of the inorganic light-emitting diodes are electrically connected to the corresponding first line through the openings, and the second pin of the one of the inorganic light-emitting diodes is electrically connected to the corresponding second line through the opening.

4. The light-emitting panel according to claim 1, wherein in one of the at least one light-emitting control region, the inorganic light-emitting diodes are arranged as a plurality of pixel rows and a plurality of pixel columns, one of the pixel rows comprises a plurality of the inorganic light-emitting diodes arranged sequentially along the first direction, and one of the pixel columns comprises a plurality of the inorganic light-emitting diodes arranged sequentially along the second direction;
wherein the one of the at least one light-emitting control region has a plurality of signal channels, each of the signal channels comprises one pixel row or a plurality of adjacent pixel rows, and the first pins of each of the inorganic light-emitting diodes in the signal channel are electrically connected;
wherein second pins of inorganic light-emitting diodes in one of the pixel columns are connected to one or more second lines, and in response to a plurality of inorganic light-emitting diodes being located in a same pixel column and in a same signal channel, the second pins of the plurality of inorganic light-emitting diodes in the same pixel column and in the same signal channel are connected to different second lines, respectively.

5. The light-emitting panel according to claim 4, wherein one of the signal channels comprises one pixel row, and the second pins of each of the inorganic light-emitting diodes in one of the pixel columns are connected to a same second line; or
wherein one of the signal channels comprises two adjacent pixel rows, the second pins of a part of the inorganic light-emitting diodes in one of the pixel columns are connected to a first second line, and the second pins of the other part of the inorganic light-emitting diodes in the one of the pixel columns are connected to a second second line, and the first and second second lines pass through regions where corresponding inorganic light-emitting diodes are located by passing between two first pins of the corresponding inorganic light-emitting diodes.

6. (canceled)

7. The light-emitting panel according to claim 4, wherein one of the signal channels comprises three adjacent pixel rows, the second pins of a part of the inorganic light-emitting diodes in one of the pixel columns are connected to a first second lines, the second pins of another part of the inorganic light-emitting diodes in the one of the pixel columns are connected to a second second line, the second pins of a further part of the inorganic light-emitting diodes in the one of the pixel columns are connected to a third second line, and the first to third second lines pass through regions where corresponding inorganic light-emitting diodes are located by passing between two first pins of the corresponding inorganic light-emitting diodes.

8. The light-emitting panel according to claim 4, wherein the light-emitting panel further comprises: first pads and first interconnect lines which are in a one-to-one correspondence with the signal channels, and second pads and second interconnect lines which are in a one-to-one correspondence with second lines;
wherein at least one first line in one of the signal channels and a corresponding first pad are electrically connected through a corresponding first interconnect line;
wherein one of the at least one second line and a corresponding second pad are electrically connected through a corresponding second interconnect line.

9. The light-emitting panel according to claim 8, wherein at least one second interconnect line or at least one first interconnect line comprises a plurality of sections of interconnect sub-lines which are arranged in a same layer as the first line, and two adjacent interconnect sub-lines are electrically connected through a jumper resistor arranged in a same layer as the inorganic light-emitting diodes.

10. The light-emitting panel according to claim 4, wherein the light-emitting panel further comprises: a plurality of second control chips arranged along the first direction, and a plurality of first control chips arranged along the second direction;
wherein one of the first control chips has one or more first output pins, and the one or more first output pins are used to apply a first voltage to a first line of a corresponding signal channel under control of the one of the first control chips;
wherein one of the second control chips has one or more second output pins, and the one or more second output pins are used to apply a second voltage to a corresponding second line under control of the one of the second control chips;
wherein one of the inorganic light-emitting diodes emits light under control of the first voltage and the second voltage.

11. The light-emitting panel according to claim 10, wherein one of the first control chips comprises a data input pin and a data output pin, and
wherein in two adjacent first control chips, a data output pin of one of the two first control chips is electrically connected to a data input pin of the other one of the two first control chips through a first data line which is arranged in a same layer as the at least one first line;
wherein the light-emitting panel further comprises a plurality of first power supply lines which are arranged in a same layer as the at least one first line and extend along the second direction, and the first power supply lines are used to provide a required voltage to the first control chips.

12. The light-emitting panel according to claim 11, wherein in a plurality of adjacent first control chips, a same first power supply line is electrically connected to each of the plurality of adjacent first control chips; or
wherein one of the first control chips comprises multiple types of power pins, the number of each type of power pins is two and each type of power pins are arranged oppositely along the second direction, and two power pins of a same type are electrically connected inside the one of the first control chips;
wherein among a plurality of adjacent first control chips, a power pin of one of two adjacent first control chips is electrically connected to a power pin of a same type of the other one of the two adjacent first control chips through a corresponding first power supply line.

13. (canceled)

14. The light-emitting panel according to claim 11, wherein the first pins are anode pins;
wherein the first power supply lines comprises a first reference voltage line for applying a reference voltage signal to the first control chips, a first chip power supply line for applying a chip power supply voltage to the first control chips, and a driving voltage signal line for applying a driving voltage signal to the first control chips;
wherein when a first output pin outputs the first voltage, the first output pin outputs the driving voltage signal to each connected inorganic light-emitting diode.

15. The light-emitting panel according to claim 10, wherein one of the second control chips comprises a data input pin and a data output pin, and in two adjacent second control chips, a data output pin of one of the two adjacent control chips is electrically connected to a data input pin of the other one of the two adjacent second control chips through a second data line which is arranged in a same layer as the at least one second line;
wherein the light-emitting panel further comprises a plurality of second power supply lines which are arranged in a same layer as the at least one second line and extend along the first direction, and the plurality of second power supply lines are used to provide a required voltage to the second control chips.

16. The light-emitting panel according to claim 15, wherein in a plurality of adjacent second control chips, a same second power supply line is electrically connected to each of the plurality of adjacent second control chips; or;
wherein one of the second control chips comprises multiple types of power pins, the number of each type of power pins is two and each type of power pins are arranged oppositely along the first direction, and two power pins of a same type are electrically connected inside the second control chip;
wherein among a plurality of adjacent second control chips, two adjacent power pins of a same type in two adjacent second control chips are electrically connected through a second power supply line.

17. (canceled)

18. The light-emitting panel according to claim 15, wherein the second pin is a cathode pin;
wherein the second power supply lines comprises a second reference voltage line for applying a reference voltage signal to the second control chips and a second chip power supply line for applying a chip power supply voltage to the second control chips, and the second control chips is are to control electrical conduction or cutoff between the second lines and the second reference voltage line.

19. The light-emitting panel according to claim 1, wherein the number of the at least one second pins in one of the inorganic light-emitting diodes is two and the second pins are electrically connected within the one of the inorganic light-emitting diodes;
wherein at least part of the at least one second line passes through a region where one of the inorganic light-emitting diodes is located by passing between the two second pins.

20. A backlight module, comprising a light-emitting panel;
wherein the light-emitting panel comprises at least one light-emitting control region, wherein in any one of the at least one light-emitting control region, the light-emitting panel comprises inorganic light-emitting diodes distributed in an array and comprises at least one first line extending along a first direction and at least one second line extending along a second direction;
wherein one of the inorganic light-emitting diodes has a plurality of first pins and a second pin, and the plurality of first pins are electrically connected inside the one of the inorganic light-emitting diodes;
wherein a first pin of one of two inorganic light-emitting diodes adjacent along the first direction is electrically connected to an adjacent first pin of the other one of the two inorganic light-emitting diodes through a corresponding first line, the second pin of one of the inorganic light-emitting diodes is electrically connected to a corresponding second line, and the second line passes through a region where the one of the inorganic light-emitting diodes is located by passing between two first pins of the one of the inorganic light-emitting diodes.

21. An inorganic light-emitting diode, wherein the inorganic light-emitting diode has a plurality of first pins and at least one second pin, and the plurality of first pins are electrically connected inside the inorganic light-emitting diode.

22. The inorganic light-emitting diode according to claim 21, wherein the number of the plurality of first pins in the inorganic light-emitting diode is two, and there is a wiring region between the two first pins, and the wiring region is used for laying out at least one line; or
wherein the number of the at least one second pins is two, and the two second pins are electrically connected inside the inorganic light-emitting diode.

23. The inorganic light-emitting diode according to claim 22, wherein a width of the wiring region is in a range of 100 to 450 microns.

24. (canceled)
